(19) United States
(12) Patent Application Publication
(10) Pub. No.: US 2010/0188891 A1
(43) Pub. Date: Jul. 29, 2010

(54) SEMICONDUCTOR DEVICE

(76) Inventors: Yasuhiro Taniguchi, Tokyo (JP); Kosuke Okuyama, Tokyo (JP)

Correspondence Address: MILES & STOCKBRIDGE PC, 1751 PINNACLE DRIVE, SUITE 500, MCLEAN, VA, 22102-3833, US

(21) Appl. No.: 12/676,387

(22) PCT Filed: Sep. 8, 2008
(86) PCT No.: PCT/JP2008/066164

§ 371 Date: Mar. 4, 2010

(30) Foreign Application Priority Data
Sep. 7, 2007 (JP) JP2007/067472

(51) Int. Cl. G11C 11/00; G11C 5/14

(52) U.S. Cl. 365/158; 365/226

(57) ABSTRACT

The semiconductor device has: a first magnetoresistance element; a second magnetoresistance element. The first and second magnetoresistance elements each includes a free layer which can be changed in spin orientation therein and a pinned layer which is fixed in spin orientation therein. The first magnetoresistance element is coupled to a first transistor at the free layer, and to a first power-source terminal at the pinned layer. The second magnetoresistance element is coupled to a second transistor at the free layer, and to the first power-source terminal at the pinned layer. In this device, the reliability of stored data is increased by preventing an undesired resistance condition's change in a magnetoresistance memory cell.

### FIELD OF THE INVENTION

The present application relates to a memory cell including a variable-resistance element, such as a magnetoresistive memory cell, an electric-field-induced-resistance memory cell or a phase-change memory cell, and a semiconductor device using the same. Particularly, it relates to a technique useful for application to e.g. MRAM (Magnetroresistive Random Access Memory), which is a nonvolatile memory using TMR (Tunnel Magneto-Resistance) effect.

### BACKGROUND OF THE INVENTION

MRAM, a nonvolatile memory using TMR effect based on the spin-dependent electrical transport has been used previously. MRAM has excellent features such as an infinitude number of owerwrites, a larger capacity owing to the scale-down of TMR devices, high-speed operation, and a low-voltage operation. A device working as a memory has a structure referred to as “TMR structure”, in which two magnetic films are arranged to sandwich a tunnel isolation layer there between. The lower magnetic film is termed “pinned layer”, and the upper magnetic film is termed “free layer”, which are both composed of a multilayer of alloy having magnetism.

The orientation of magnetism (spin orientation) in the layer of the free layer can be changed by causing current to pass through the layer. The pinned layer is less prone to change or in the orientation of magnetism in the layer or never exhibit such change even though current can flow therein, in comparison to the free layer. In regard to a memory operation, the orientation of magnetism of a free layer can be controlled by fixing the orientation of magnetism of a pinned layer, and then applying an external magnetic field induced by current to TMR device. The resistance condition of a tunnel current running through the tunnel isolation film is changed depending on whether the orientation of magnetism of a free layer is parallel or antiparallel with the orientation of magnetism of a pinned layer. The changes so produced correspond to logical values “0” and “1” for memory operations

Examples literatures reporting MRAM include the following patent documents:

JP-A-63-136386, and JP-A-2002-511631.

### SUMMARY OF THE INVENTION

A magnetoresistance memory cell using TMR effect can be formed by a combination of one transistor and one resistance. In this case, the change in voltage of a bit line attributed to the change in resistance is sensed. Such cell is termed “1Tr+1R type cell”. For a resistive portion of a cell like this, MTJ (Magnetic Tunnel Junction) is used in the case of MRAM. Especially, MRAM has a resistance ratio as small as about 50 to 70 percent and therefore, a differential-amplification type sense amplifier using a reference bit line is often used for reading the change in bit line voltage.

In general, as to a differential-amplification type sense amplifier, the sensing time is shortened, which enables a high-speed read action. However, if there is no differentially amplifying function in a memory cell, the potential fluctuation of a bit line must be offset by the discharging ability of a series circuit composed of a transistor and a resistance in the memory cell, and the high-seed action is restricted by the limit of such ability.

In contrast, according to the above patent documents, a memory cell with a differentially amplifying function provided therein can work at a high speed, however a current flowing through a resistance element causes an undesired resistance condition change, which would lead to a destruction of data, and therefore caution is exercised. However, the patent documents cited above both contain no concrete description about the problem.

It is an object of the invention to provide a technique for forming a memory cell which achieves the improvement in the reliability of stored data.

It is another object of the invention to provide a technique for performing an access for e.g. a write action with stability in a semiconductor device using a memory cell including a variable-resistance element, such as a magnetoresistance memory cell, an electric-field-induced-resistance memory cell or a phase-change memory cell.

The above and other object of the invention and novel features thereof will be apparent from the description hereof and the

Of preferred embodiments of the invention herein disclosed, a representative one will be outlined below briefly.

Specifically, a semiconductor device according to the preferred embodiment is provided with first and second magnetoresistance elements. The first and second magnetoresistance elements each include a free layer which can be changed in spin orientation therein, and a pinned layer which is fixed in spin orientation therein. The first magnetoresistance element is coupled to a first transistor at the free layer side thereof, and to a first power-source terminal at the pinned layer side. The second magnetoresistance element is coupled to a second transistor at the free layer side, and to the first power-source terminal at the pinned layer side. The reliability of stored data is improved by preventing undesired resistive state changes in a magnetoresistance memory cell.

The effect achieved by the preferred embodiment of the invention herein disclosed is as follows briefly.

The improvement in the reliability of stored data can be achieved by preventing a undesired resistive state changes in a magnetoresistance memory cell.

### BRIEF DESCRIPTION OF THE DRAWINGS

FIG. 1 is a block diagram showing an example of the structure of a semiconductor memory device, which is an example of a semiconductor device in connection with the invention;

FIG. 2 is a diagram for explaining an example of the structure of magnetoresistance elements included in the semiconductor device;

FIGS. 3A-3D are diagrams for explaining the change in condition of the magnetoresistance element shown in FIG. 2;

FIGS. 4A-4F are diagrams for explaining an example of the structure of the magnetoresistance element;

FIG. 5 is a circuit diagram showing an example of structure of a magnetoresistance memory cell included in the semiconductor device;

FIG. 6 is a circuit diagram for explaining an action on the magnetoresistance memory cell shown in FIG. 5;

FIG. 7 is a timing chart of an action in connection with a staple portion of the magnetoresistance memory cell shown in FIG. 5 during overwrite;

FIGS. 8A and 8B are each another circuit diagram for explaining an action on the magnetoresistance memory cell shown in FIG. 5;

FIG. 9 is a timing chart of an action in connection with the staple portion of the magnetoresistance memory cell shown in FIG. 5 during overwrite;

FIG. 10 is a circuit diagram showing another example of the structure of the magnetoresistance memory cell included in the semiconductor device;

FIGS. 11A and 11B are each a circuit diagram for explaining an action on the magnetoresistance memory cell shown in FIG. 10;

FIG. 12 is a timing chart of an action in connection with a staple portion of the magnetoresistance memory cell shown in FIG. 10 during overwrite;

FIGS. 13A and 13B are each a circuit diagram for explaining an action on the magnetoresistance memory cell shown in FIG. 10;

FIG. 14 is a timing chart of an action in connection with a staple portion of the magnetoresistance memory cell shown in FIG. 10 during overwrite;

FIGS. 15A and 15B are each a circuit diagram for explaining an action on the magnetoresistance memory cell shown in FIG. 10;

FIG. 16 is a timing chart of an action in connection with a staple portion involved with the startup sequence of the magnetoresistance memory cell shown in FIG. 10;

FIGS. 17A-17D are plane views each showing a layout of the magnetoresistance memory cell shown in FIG. 5 in a step in the course of the manufacture thereof;

FIG. 18A is a plane view showing a layout of the magnetoresistance memory cell shown in FIG. 5;

FIG. 18B is a sectional view of a staple portion of the magnetoresistance memory cell taken along the line A-A′ of FIG. 18A;

FIGS. 19A-19F are plane views each showing a layout of the magnetoresistance memory cell shown in FIG. 10 in a step in the course of the manufacture thereof;

FIG. 20A is a plane view showing a layout of the magnetoresistance memory cell shown in FIG. 10;

FIG. 20B is a sectional view of a staple portion of the magnetoresistance memory cell taken along the line B-B′ of FIG. 20A;

FIG. 21 is a diagram for explaining correspondences between the magnetoresistance memory cell shown in FIG. 10, and the layouts shown in FIGS. 19A-19F and 20A;

FIG. 22 is a block diagram showing an example of the configuration of a microcomputer, which is an example of application of a semiconductor device in connection with the invention;

FIG. 23 is a circuit diagram showing an example of configuration of a staple portion of a main memory included in the microcomputer;

FIGS. 24A and 24B are circuit diagrams showing an example of configuration of a staple portion of the semiconductor memory device;

FIG. 25 is a circuit diagram showing another example of configuration of the staple portion of the semiconductor memory device;

FIG. 26 is a timing chart of another action in connection with the staple portion of the semiconductor memory device;

FIG. 27 is a timing chart of another action in connection with the staple portion of a semiconductor memory device;

FIG. 28 is a timing chart of another action in connection with the staple portion of the semiconductor memory device;

FIGS. 29A-29D are circuit diagrams for explaining an action in a staple portion of the semiconductor memory device;

FIGS. 30A and 30B are each a circuit diagram for explaining a procedure for overwriting the magnetoresistance memory cell shown in FIG. 5;

FIGS. 31A and 31B are each a circuit diagram for explaining a procedure for overwriting the magnetoresistance memory cell shown in FIG. 10;

FIGS. 32A-32F are each a diagram for explaining another example of the structure of the magnetoresistance elements;

FIG. 33 is a plane view showing another layout of the magnetoresistance memory cell shown in FIG. 10;

FIG. 34 is a sectional view of a staple portion of the magnetoresistance memory cell shown in FIG. 10 taken along the line C-C′ of FIG. 33;

FIG. 35 is a plane view showing another layout of a staple portion in the magnetoresistance memory cell shown in FIG. 10;

FIG. 36 is a plane view showing another layout of a staple portion in the magnetoresistance memory cell shown in FIG. 10; and

FIG. 37 is a sectional view of the staple portion of the magnetoresistance memory shown in FIGS. 35 and 36.

### DETAILED DESCRIPTION OF THE PREFERRED EMBODIMENTS

### 1. Summary of the Preferred Embodiments

The preferred embodiments of the invention herein disclosed will be outlined, first. Here, the reference numerals, characters and signs for reference to the drawings, which are accompanied with paired round brackets, only exemplify what the concepts of components and elements referred to by the numerals, characters and signs contain.

[1] A magnetoresistance memory cell (MC) of a semiconductor device according to a preferred embodiment of the invention includes: a first power-source terminal (207) for supply of a high-potential side power source; a second power-source terminal (208) for supply of a low-potential side power source, a first magnetoresistance element (203) and a second magnetoresistance element (204), which are connected with the first power-source terminal individually, and a first transistor (205) and a second transistor (206), which are connected with the second power-source terminal individually. The first magnetoresistance element and first transistor are connected in series; a series-connection node of the first magnetoresistance element and first transistor thus series-connected is coupled to a control terminal of the second transistor. The second magnetoresistance element and second transistor are connected in series; a series-connection node of the second magnetoresistance element and second transistor thus series-connected is coupled to a control terminal of the first transistor. The first and second magnetoresistance elements each include a free layer which can be changed in spin orientation therein, and a pinned layer which is fixed in spin orientation therein. The first magnetoresistance element is coupled to the first transistor at the free layer side thereof, and to the first power-source terminal at the pinned layer side. The second magnetoresistance element is coupled to the second transistor at the free layer side, and to the first power-source terminal at the pinned layer side.

[2] The magnetoresistance memory cell may include: a third transistor (201) through which the series-connection node of the first magnetoresistance element and first transistor can be coupled to a first bit line; and a fourth transistor (202) through which the series-connection node of the second magnetoresistance element and second transistor can be coupled to a second bit line in a complementary relation in level with the first bit line.

[3] A magnetoresistance memory cell (MC) of a semiconductor device according to another preferred embodiment of the invention includes a first power-source terminal (309) for supply of a high-potential side power source, a second power-source terminal (310) for supply of a low-potential side power source, and a first magnetoresistance element (303) and a second magnetoresistance element (304), which are coupled to the first power-source terminal individually. Further, the magnetoresistance memory cell (MC) includes a first conductivity type of a first transistor (305) coupled to the first magnetoresistance element, a second conductivity type of a second transistor (306) coupled to the second power-source terminal, a first conductivity type of a third transistor (307) coupled to the second magnetoresistance element, and a second conductivity type of a fourth transistor (308) coupled to the second power-source terminal. The first and second transistors are connected in series. The third and fourth transistors are connected in series. The series-connection node of the first and second transistors is coupled to a control terminal of the third and fourth transistors. The series-connection node of the third and fourth transistors is coupled to a control terminal of the first and second transistors. The first and second magnetoresistance elements each include a free layer which can be changed in spin orientation therein, and a pinned layer which is fixed in spin orientation therein. The first magnetoresistance element is coupled to the first power-source terminal at the free layer side, and to the first transistor at the pinned layer side. The second magnetoresistance element is coupled to the first power-source terminal at the free layer side, and to the third transistor at the pinned layer side.

[4] The magnetoresistance memory cell further includes a fifth transistor (301) through which the series-connection node of the first and second transistors, and the control terminal of the third and fourth transistors can be connected to a first bit line. Further, the magnetoresistance memory cell includes a sixth transistor (302) through which the series-connection node of the third and fourth transistors, and the control terminal of the first and second transistors can be connected to a second bit line in a complementary relation in level with the first bit line.

[5] The semiconductor device may include: a plurality of magnetoresistance memory cells as described in [2]; and a control circuit (18) which controls the voltage level of the first power-source terminal into substantially half of the voltage between the first and second bit lines on condition that information for write on the magnetoresistance memory cell has been stored by the first and second bit lines thereby to enable an overwrite on the magnetoresistance memory cell.

[6] The semiconductor device may include: a plurality of magnetoresistance memory cells as described in [2]; and a control circuit (18) which controls the voltage level of the first power-source terminal into a level substantially equal to a high level of the information for write in the first and second bit lines on condition that data to be written on the magnetoresistance memory cell is stored by the first and second bit lines, and after an elapse of a predetermined length of time, controls the voltage level of the first power-source terminal into a voltage substantially equal to a low level of the information for write in the first and second bit lines thereby to enable an overwrite on the magnetoresistance memory cell.

[7] The semiconductor device may include: a plurality of magnetoresistance memory cells as described in [4]; and a control circuit (18) which brings both the first and second bit lines to a level substantially equal to the voltage level of the second power-source terminal, and in this condition, controls a voltage level of the first power-source terminal to a level substantially equal to the high level of the information for write in the first and second bit lines, thereby to put the first and second magnetoresistance elements in the same resistance condition, and then controls the voltage level of the first power-source terminal to a level lower than the high level of the information for write on condition that information for write on the magnetoresistance memory cell has been stored by the first and second bit lines thereby to enable an overwrite on the magnetoresistance memory cell.

[8] A semiconductor device according to the invention includes: a plurality of magnetoresistance memory cells as described in [4]; and a control circuit (18) operable to bring both the first and second bit lines to a level substantially equal to the voltage level of the second power-source terminal, and in this condition, control the voltage level of the first power-source terminal to a level midway between high and low levels of the information for write in the first and second bit lines. The control circuit controls the voltage level of the first power-source terminal to a level midway between high and low levels of the information for write in the first and second bit lines, and after an elapse of a predetermined length of time, the information for write on the magnetoresistance memory cell is stored by the first and second bit lines, whereby an overwrite on the magnetoresistance memory cell is enabled.

[9] A semiconductor device according to the invention includes: a plurality of magnetoresistance memory cells as described in [4]; and a control circuit (18) operable to control voltage supply to the magnetoresistance memory cells. The control circuit has a startup sequence control mode after power source cutoff. In the startup sequence control mode, the first power source, and first and second bit lines are made equal to the second power source in voltage level. In this condition, the fifth and sixth transistors are brought into conduction, whereby a potential of the series-connection node of the first and second transistors, and a potential of the series-connection node of the third and fourth transistors are made identical. After that, the potential of the series-connection node of the first and second transistors, and the potential of the series-connection node of the third and fourth transistors are restored according to resistance conditions of the first and second resistance elements.

[10] The semiconductor device further includes: a plurality of word lines (WL1, WL2); a plurality of bit lines (BL1, BL1B, BL2, BL2B) laid out to intersect with the plurality of word lines; and a plurality of memory cells (MC) laid out at points where the word lines and bit lines intersect with each other. In regard to the semiconductor device, the memory cells correspond to the magnetoresistance memory cells described in [2] or [4], the magnetoresistance memory cells are organized into memory cell groups each sharing one word line, and the voltage-supplying lines (PL1, PL2) enable voltage supply to the first power-source terminal for each memory cell group.

[11] In the semiconductor device as described in [10], the voltage-supplying lines are coupled to the corresponding word lines.

[12] The semiconductor device includes: a plurality of word lines; a plurality of bit lines laid out to intersect with the plurality of word lines; and a plurality of memory cells laid out at points where the word lines and bit lines intersect with each other. With this semiconductor device, the memory cells correspond to the magnetoresistance memory cells described in [2] or [4]. The semiconductor device further includes a plurality of voltage-supplying lines, in which the magnetoresistance memory cells are organized into memory cell groups each sharing one bit line, and the voltage-supplying lines enable voltage supply to the first power-source terminal for each memory cell group.

[13] In the semiconductor device including a plurality of individually selectable memory mats, the memory mat has a plurality of word lines, a plurality of bit lines laid out to intersect with the plurality of word lines, a plurality of memory cells laid out at points where the word lines and bit lines intersect with each other, and a control circuit operable to enable voltage supply to the first power-source terminals in the magnetoresistance memory cells involved in the selected memory mat. In this case, the memory cells correspond to the magnetoresistance memory cells described in [2] or [4].

[14] A semiconductor device having a first memory (221) including the magnetoresistance memory cells described in [1] or [3], a second memory (224) including a plurality of memory cells each composed of a magnetoresistance element and a transistor, which are connected in series, and a central processing unit (223) capable of accessing the first and second memories can be constructed.

[15] In the semiconductor device as described in [3], the following two can be prepared as an access mode for the first memory: a volatile write mode, in which information is written on one of the memories without changing resistance conditions of the first and second resistance elements; and a nonvolatile write mode, in which information is written on one of the memories while changing the resistance condition of the first or second resistance element.

[16] The semiconductor device includes: a first power-source terminal (207) for supply of a high-potential side power source; a second power-source terminal (208) for supply of a low-potential side power source; a first magnetoresistance element (203) and a second magnetoresistance element (204), which are connected with the first power-source terminal individually; and a first transistor (205) and a second transistor (206), which are connected with the second power-source terminal individually. In the semiconductor device, the first magnetoresistance element and first transistor are connected in series, and the series-connection node thereof is coupled to a control terminal of the second transistor. The second magnetoresistance element and second transistor is connected in series, and the series-connection node thereof is coupled to a control terminal of the first transistor. The semiconductor device further includes a third transistor through which the series-connection node of the first magnetoresistance element and first transistor can be coupled to a first bit line, and a fourth transistor through which the series-connection node of the second magnetoresistance element and second transistor can be coupled to the second bit line in a complementary relation in level with the first bit line. When the third and fourth transistors are brought into conduction with a predetermined voltage applied to between the first bit line and first power-source terminal, an overwrite on the first magnetoresistance element is enabled. Further, when the third and fourth transistors are brought into conduction with a predetermined voltage applied to between the second bit line and first power-source terminal, an overwrite on the second magnetoresistance element is enabled.

[17] The semiconductor device includes: a first power-source terminal (309) for supply of a high-potential side power source; a second power-source terminal (310) for supply of a low-potential side power source; a first magnetoresistance element (303) and a second magnetoresistance element (304), which are coupled to the first power-source terminal individually; a first transistor (305) of a first conductivity type coupled to the first magnetoresistance element; a second transistor (306) of a second conductivity type coupled to the second power-source terminal; a third transistor (307) of a first conductivity type coupled to the second magnetoresistance element; and a fourth transistor (308) of a second conductivity type coupled to the second power-source terminal. In the semiconductor device, the first and second transistors are connected in series, the third and fourth transistors are connected in series, the series-connection node of the first and second transistors is coupled to the control terminal of the third and fourth transistors, and the series-connection node of the third and fourth transistors is coupled to the control terminal of the first and second transistors. Further, the semiconductor device has a fifth transistor (301) through which the series-connection node of the first and second transistors, and the control terminal of the third and fourth transistors can be coupled to a first bit line, and a sixth transistor (308) through which the series-connection node of the third and fourth transistors, and the control terminal of the first and second transistors can be coupled to a second bit line in a complementary relation in level with the first bit. When the fifth and sixth transistors are brought into conduction with a predetermined voltage applied to between the first bit line and first power-source terminal, an overwrite on the first magnetoresistance element is enabled. When the fifth and sixth transistors are brought into conduction with a predetermined voltage applied to between the second bit line and first power-source terminal, an overwrite on the second magnetoresistance element is enabled.

[18] The semiconductor device as described in [16] or [17] may be provided with a control circuit which enables a verify for confirming whether or not the first and second magnetoresistance elements have a desired value after overwrite on the magnetoresistance memory cell.

[19] The semiconductor device as described in [16] has: a control circuit which makes possible to verify whether or not the first and second magnetoresistance elements have a desired value after overwrite on the magnetoresistance memory cell; and a sense amplifier which enables latching data read from the magnetoresistance memory cell. The control circuit makes the first and second bit lines a voltage equal to the potential level of the second power-source terminal, brings the third and fourth transistors into conduction, and then makes a judgment about whether or not an expected value has been latched with the sense amplifier within a predetermined length of time, whereby the verify is enabled.

[20] The semiconductor device as described in [17] has a control circuit which enables a verify about whether or not the first and second magnetoresistance elements have a desired value after overwrite on the magnetoresistance memory cell. Therefore, the semiconductor device is provided with a sense amplifier which is capable of latching data read from the magnetoresistance memory cell. The control circuit is arranged to enable a verify by taking the steps of: after data write on the magnetoresistance memory cell, making voltages of the first and second bit lines equal to the potential level of the second power-source terminal; raising the voltages of the first and second bit lines to the level of the high-potential side power source on condition that the fifth and sixth transistors remain nonconducting; bringing the fifth and sixth transistors into conduction; and then judging whether or not an expected value has been latched by the sense amplifier within a predetermined length of time.

[21] For the semiconductor device as described in [16] or [17], the following two modes may be prepared: a first read mode serving as a mode for read from the magnetoresistance memory cell, which makes possible to read on condition that the semiconductor device stays off at first; and a second read mode, which makes possible to read on condition that the semiconductor device remains powered on.

[22] The semiconductor device has: a first memory (224) including a magnetoresistance memory cell as described in [16] or [17]; a second memory (221) including a plurality of memory cells each composed of a magnetoresistance element and a transistor, which are connected in series; and a central processing unit (223) capable of accessing the first and second memories. The first memory serves as a cache memory when the central processing unit reads data from the second memory.

[23] The semiconductor device has: a first memory (224) including a magnetoresistance memory cell as described in [16] or [17]; a second memory (221) including a plurality of memory cells each composed of a magnetoresistance element and a transistor, which are connected in series; and a central processing unit (223) capable of accessing the first and second memories. The first and second memories are coupled so that mutual data exchange can be performed.

[24] In the semiconductor device as described in [3] or [17], the first and third transistors are next to each other with the diffusion layers thereof separated from each other.

[25] The semiconductor device as described in [4] is arranged as follows. The second, fourth, fifth and sixth transistors are formed on a top face of a semiconductor substrate. The first and third transistors are formed in positions higher than positions of the second, fourth, fifth and sixth transistors in a direction perpendicular to the top face of the substrate. The first magnetoresistance element is disposed between the first transistor and first power-source terminal. The second magnetoresistance element is disposed between the third transistor and first power-source terminal. As a result, an undesirous increase of the cell footprint can be avoided.

### 2. Further Detailed Description of the Preferred Embodiments

Now, the preferred embodiments will be described further in detail.

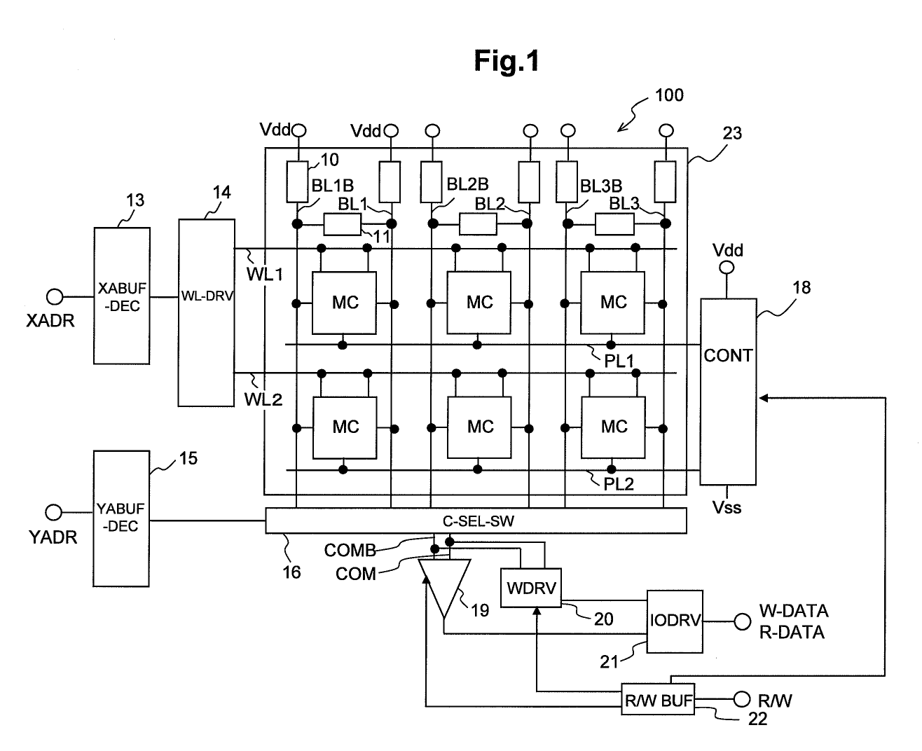

FIG. 1 shows a semiconductor memory device as an example of a semiconductor device in connection with the invention.

Although no special restriction is intended, the semiconductor memory device 100 shown in FIG. 1 includes: a memory cell array 23; an X address buffer/decoder (XABUF-DEC) 13; a word-line driver (WL-DRV) 14; a Y address buffer/decoder (YABUF-DEC) 15; a column-select switch (C-SEL-SW) 16; a control circuit (CONT) 18; a sense amplifier 19; a write driver (WDRV) 20; an input/output buffer (IODRV) 21; and an R/W buffer (R/WBUF) 22, which is formed on a semiconductor substrate, such as a monocrystalline silicon substrate, using the well-known semiconductor IC manufacturing techniques.

The memory cell array 23 has a plurality of word lines WL1 and WL2, and a plurality of pairs of complementary bit lines BL1 and BL1B, BL2 and BL2, and BL3 and BL3B, which are laid out to intersect one another, and magnetoresistance memory cells MC disposed at intersection points thereof. The pairs of complementary bit lines BL1 and BL1B, BL2 and BL2B, and BL3 and BL3B are coupled to the high-potential side power source Vdd through predetermined bit-line loads 10 respectively. For the pairs of complementary bit line BL1 and BL1B, BL2 and BL2B, and BL3 and BL3B, an equalizing circuit 11 for equalizing the potential level between complementary bit lines of each pair with a predetermined timing is provided.

The X address buffer/decoder 13 buffers and decodes an input X (Row) address signal. A result of the X address signal decoding is delivered to the word-line driver 14 disposed in a subsequent stage. According to an output signal from the word-line driver 14, of the plurality of word lines WL1 and WL2, a word line specified by the X address signal is driven to a select level.

The Y address buffer/decoder 15 buffers and decodes an input Y (column) address. A result of the Y address signal decoding is delivered to the column-select switch circuit 16. The column-select switch circuit 16 includes a plurality of switches for selectively connecting the pairs of complementary bit lines BL1 and BL1B, BL2 and BL2B, and BL3 and BL3B to common bit lines COM and COMB. A signal read from the magnetoresistance memory cell MC is sent from the relevant pair of complementary bit lines BL1 and BL1B, BL2 and BL2B, or BL3 and BL3B through the column-select switch circuit 16 to the common bit lines COM and COMB. To the common bit lines COM and COMB, the sense amplifier 19 and write driver 20 are coupled. The sense amplifier 19 amplifies the read signal which has been delivered to the common bit lines COM and COMB through the column-select switch circuit 16. An output signal from the sense amplifier 19 can be output to the outside through the input/output buffer 21. Write data taken in through the input/output buffer 21 from outside is delivered to the common bit lines COM and COMB through the write driver 20, and then passed through the column-select switch circuit 16 to the pair of complementary bit lines specified by a Y address. At that time, the word line specified by an X address is driven to the select level, whereby data write to a certain magnetoresistance memory cell MC is enabled.

The control circuit 18 has control of the read and read actions. The control circuit 18 discriminates between a read action and a read action based on a R/W signal, and produces various voltages and control signals required for the read action and read action. Such various voltages can be delivered to the relevant magnetoresistance memory cell MC through cell-source lines PL1 and PL2.

### First Embodiment

### 4-Transistor and 2-Magnetoresistance Cell Structure

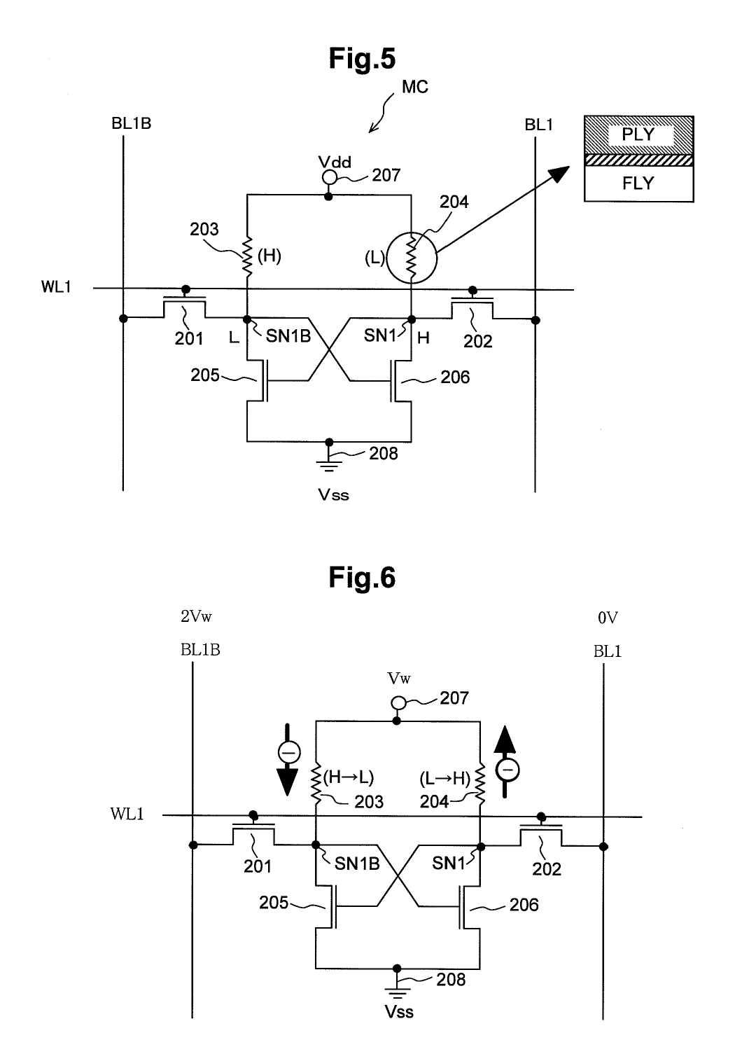

FIG. 5 shows an example of structure of the magnetoresistance memory cell MC.

As shown in FIG. 5, the magnetoresistance memory cell MC includes two magnetoresistance elements 203 and 204, and four n-channel MOS transistors 201, 202, 205 and 206. The magnetoresistance element 203 is connected with the n-channel MOS transistor 205 in series at a series-connection node, also herein referred to as “storage node”. The series-connection node SN1B is coupled to the bit line BL1B through the n-channel MOS transistor 201. Likewise, the magnetoresistance element 204 is connected with the n-channel MOS transistor 206 in series at a series-connection node, also herein referred to as “storage node”. The series-connection node SN1 is coupled to the bit line BL1 through the n-channel MOS transistor 202. The magnetoresistance elements 203 and 204 are both connected to a first power-source terminal 207. To the first power-source terminal 207, e.g. the high-potential side power source Vdd is supplied. The n-channel MOS transistors 205 and 206 are both connected to a second power-source terminal 208. The second power-source terminal 208 is supplied with e.g. a low-potential side power source Vss, which is a source voltage lower than the high-potential side power source Vdd. Incidentally, an example of the low-potential side power source Vss is the ground voltage.

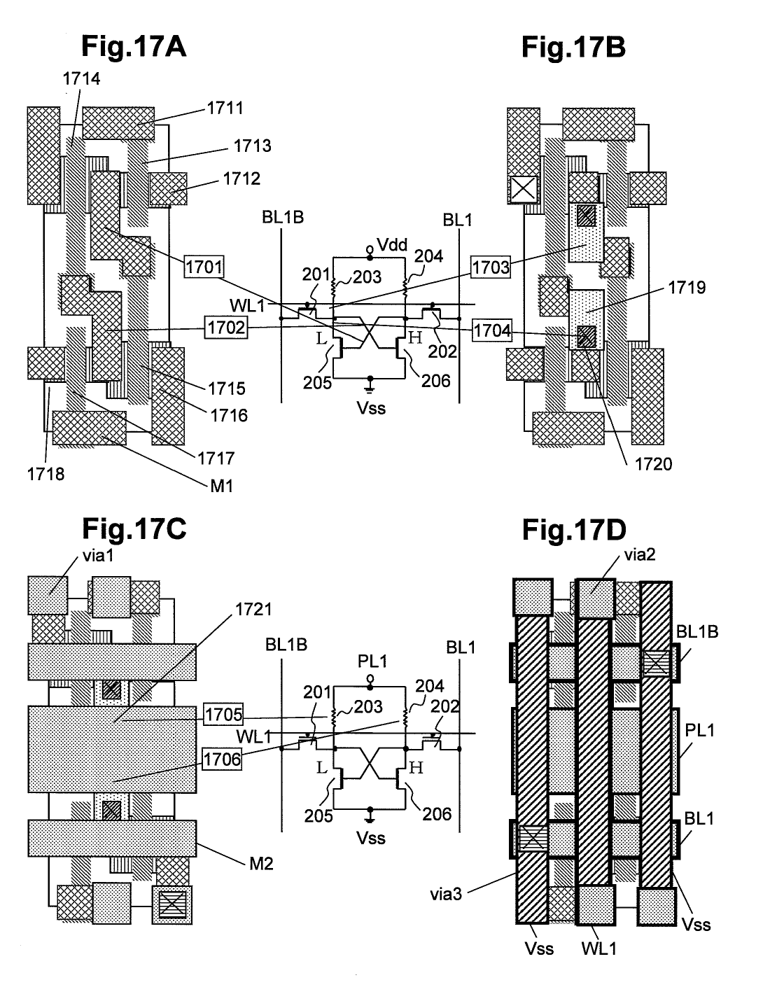

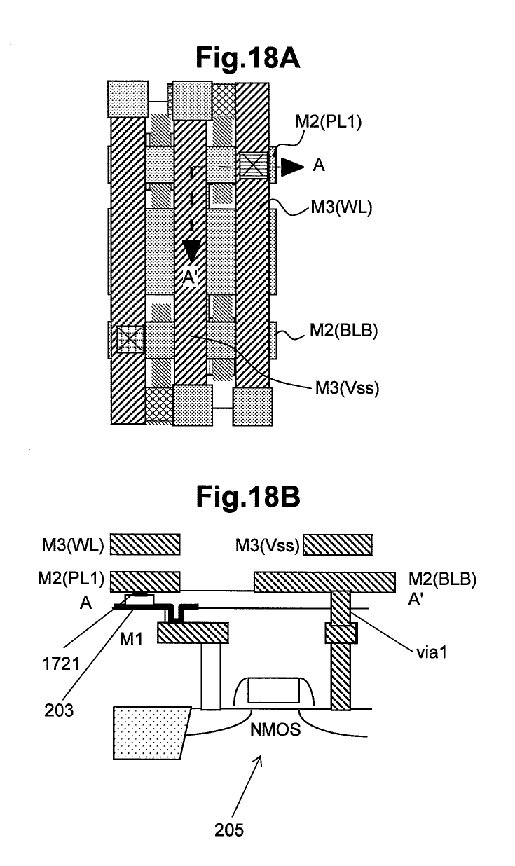

FIGS. 17A to 17D show layouts of the magnetoresistance memory cell MC shown in FIG. 5 in steps in the course of the manufacture thereof. FIG. 18A shows a layout of the magnetoresistance memory cell after completion of a series of manufacturing steps thereof. FIG. 18B presents a sectional view of the magnetoresistance memory cell MC taken along the line A-A′ of FIG. 18A.

FIG. 17A presents a plane layout at the point of the completion of formation of the first layer of metal. The reference numerals 1701 and 1702 denote a storage node, on which a magnetoresistance is formed. The numeral 1711 denotes a contact hole for connecting a gate electrode of a MOS transistor with a piece of metal wiring. The numeral 1712 denotes a contact hole for connecting an active region with a first-layer metal line. The numeral 1713 denotes a gate electrode of the MOS transistor 201. The numeral 1714 denotes a gate electrode of the MOS transistor 205. The numeral 1715 denotes a gate electrode of the MOS transistor 206. The numeral 1716 denotes an active region. The numeral 1717 denotes a gate electrode of the MOS transistor 202. The numeral 1718 denotes a separating region.

Subsequently, a magnetoresistance and a lower electrode of the resistance are formed on a line of the first-layer metal line M1 denoted by 1701 and 1703, as shown in FIG. 17B. Specifically, after covering the first-layer metal line M1 with an isolation film, openings for via holes are provided in the locations indicated by the numerals 1703 and 1704, and a wiring layer, from which the lower electrode will be shaped, is formed there by sputtering a bulk metal including e.g. tantalum (Ta) and the layer is processed. In the drawing, the reference numeral 1719 denotes the lower electrode, and 1720 denotes a contact hole for connecting the first-layer metal line with the lower electrode 1719.

After that, a magnetoresistance and its upper electrode are formed by a sputtering or oxidization technique. The layer formed by sputtering or oxidization is machined into a mesa form so that the magnetoresistive material is left only in the locations indicated by the numerals 1705 and 1706 as shown in FIG. 17C. Then, the substrate thus prepared is planarized by an isolation film.

Subsequently, first via-holes Via1 are formed on portions of the first-layer metal line, which will be connected to bit and word lines. Then, pieces of wiring which will form bit lines BL1 and BL1B and a source line PL1 are formed from a second-layer metal line M2 as shown in FIG. 17D. At this point, the upper electrode composed of the magnetoresistive portion is connected with the source line PL1.

After that, an isolation film is stacked on the workpiece, and a second via hole is formed for connecting the second-layer metal line M2 with a third-layer metal line M3, and then the third-layer metal line is formed.

A low-potential side power source terminal Vss and word line are formed from the third-layer metal line.

As the method of forming a magnetoresistive portion, the example in which the magnetoresistive portion is processed into a mesa form is shown here. However, the method is not particularly limited.

According to the layout that one source line PL1 is arranged between bit lines like this, a magnetoresistance element can be connected to a source line PL readily without a complicated interconnection.

From another perspective, according to the layout that a magnetoresistance element is arranged between bit lines, the magnetoresistance element can be connected readily only by providing one source line PL1 in the cell.

### <<Magnetoresistive Element>>

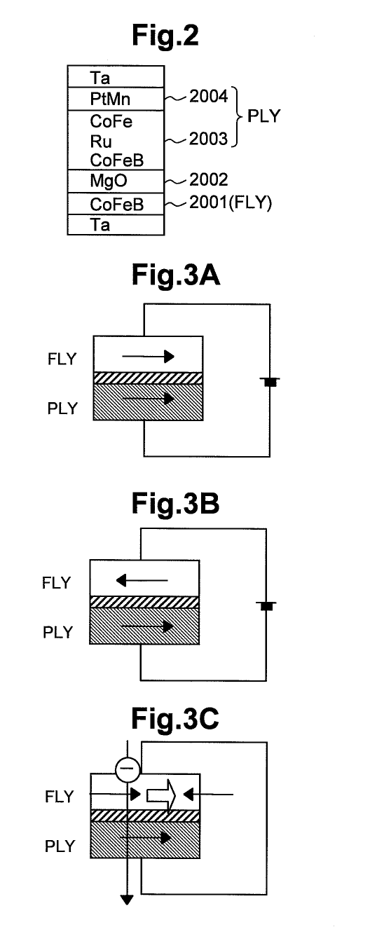

FIG. 2 shows an example of the structure of the magnetoresistance elements 203 and 204.

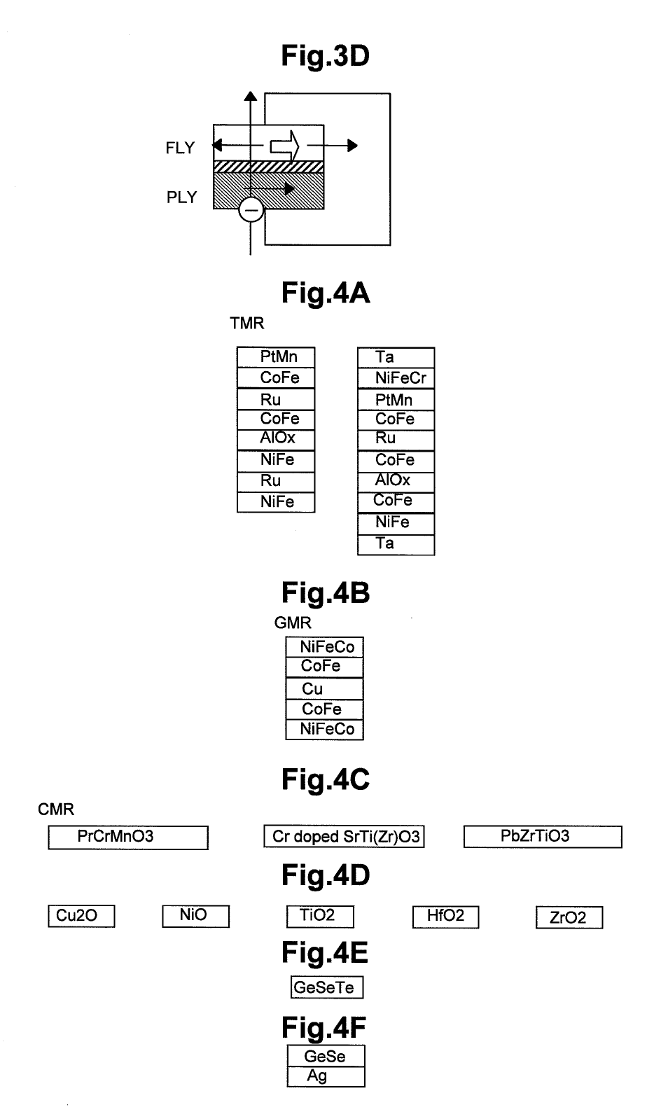

In this example, a magnetoresistance element on which the TMR effect works well is adopted for the magnetoresistance elements 203 and 204. Such magnetoresistance element is constructed as follows. First, a second ferromagnetic layer 2003 is stacked on a first ferromagnetic layer 2001 so that a tunnel isolation film 2002 is interposed therebetween. Further, an antiferromagnetic layer 2004 is stacked on the second ferromagnetic layer 2003. The first ferromagnetic layer 2001 forms a free layer FLY, and made of a cobalt-iron-boron alloy (CoFeB). A pinned layer PLY is formed by stacking the antiferromagnetic layer 2004 on the second ferromagnetic layer 2003. The second ferromagnetic layer 2003 is formed by stacking CoFeB, Ru and CoFe layers. The antiferromagnetic layer is made of platinum-manganese alloy (PtMn). Electrodes of tantalum (Ta) are formed on two opposite ends of the magnetoresistance element. The pinned layer is fixed by the antiferromagnetic layer in spin orientation and therefore, the spin orientation therein is never changed by current, magnetic field, or the like. However, the free layer consists of a ferromagnetic layer, which is aligned in the spin orientation therein, but not restricted in what directions the spin orientations are aligned with. The spin orientation can be changed by a current or magnetic field. The resistance which a tunnel current between the two electrodes opposed to each other with respect to the tunnel isolation film undergoes, hereinafter referred to as “resistance” simply, depends on the spin orientations in the free layer FLY and pinned layer PLY in value. Specifically, on condition that the free layer FLY and pinned layer PLY are identical to each other in spin orientation as shown in FIG. 3A, which is termed “parallel state”, the resistance value is small (low-resistance condition). In contrast, in the condition where the free layer FLY and pinned layer PLY are different from each other in spin orientation as shown in FIG. 3B, which is termed “antiparallel state”, the resistance value is large (high-resistance condition).

To bring the spin orientation from the parallel state to antiparallel state, it is appropriate to inject electrons from the free layer FLY to the pinned layer PLY, as shown in FIG. 3C. Thus, the spin orientation is forced to transition from the parallel state to the antiparallel state. On the contrary, to bring the spin orientation from the antiparallel state to the parallel state, it is appropriate to inject electrons from the pinned layer PLY to the free layer FLY as shown in FIG. 3D. Consequently, the spin orientation is forced to transition from antiparallel state to the parallel state. In general, a current necessary for transition of the condition has a tendency to be smaller in the transition from the parallel state to antiparallel state in comparison to the transition from the antiparallel state to parallel state.

### <<Relation of Interconnections in the 4-Transistor and 2-Magnetoresistance Cell, and Data Holding>>

With the magnetoresistance element 203, the free layer FLY is connected to the n-channel MOS transistor 205, and the pinned layer PLY is connected to the first power-source terminal 207. In regard to the magnetoresistance element 204, the free layer FLY is connected to the n-channel MOS transistor 206, and the pinned layer PLY is connected to the first power-source terminal 207. The reason for arranging the magnetoresistance elements 203 and 204 like this is as follows.

It is assumed that in the magnetoresistance memory cell MC shown in FIG. 5 staying in the standby state (data-holding state), the node SN1B is at Low level, and the node SN1 is at High level. In this case, the magnetoresistance element 203 is in the antiparallel state (high-resistance condition), and the magnetoresistance element 204 is in the parallel state (low-resistance condition). A requirement for keeping this condition in terms of electrons' flowing direction is as follows.

That is, to keep the antiparallel state (i.e. High-resistance state) of the magnetoresistance element 203, it is required that electrons flow from the free layer FLY to the pinned layer PLY as shown in FIG. 3C, in which electric current flows in an opposite direction. Appropriate steps for causing electrons to flow from the free layer to the pinned layer on condition that the high-potential side power source Vdd is being supplied to the first power-source terminal 207, and the node SN1B stays at Low level, in the case of the magnetoresistance element 203, are connecting the free layer FLY to the n-channel MOS transistor 205, and connecting the pinned layer PLY to the first power-source terminal 207.

In contrast, while the magnetoresistance element 204 stays in the parallel state (low-resistance condition), it barely has any current running therethrough because of the node SN1 at High level. Even if current flows through the magnetoresistance element 204, it flows, in terms of quantity, to such a degree that the parallel state is maintained.

Therefore, chances of transition from the parallel state to the antiparallel state are extremely remote. According to the method in connection with the invention, the resistance condition of the magnetoresistive layers 203 and 204 can be kept stable.

### <<Write Action 1 on the 4-Transistor and 2-Magnetoresistance Cell>>

Now, a procedure for overwriting the magnetoresistance memory cell MC shown in FIG. 5 will be described.

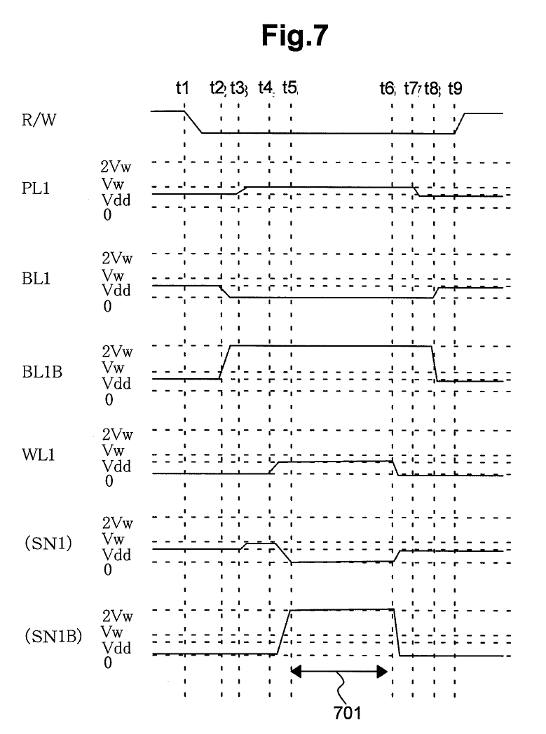

FIG. 7 shows the action timing in staple portions during overwrite on the magnetoresistance memory cell MC shown in FIG. 5.

For convenience of description, it is assumed as a condition before overwrite that the magnetoresistance element 203 stays in the antiparallel state (high-resistance condition), and the magnetoresistance element 204 is in the parallel state (low-resistance condition).

Overwrite is directed by turning the read/write signal R/W to Low level (t1). Then, as shown in FIG. 6, the bit line BL1 is made to transition from the Vdd level to Vss level (0-volt level), and the bit line BL1B is made to transition from the Vdd level to the 2Vw level (t2). Here, Vw represents a write voltage, and the relation Vw>Vdd holds.

The control circuit 18 thereafter turns the potential of the cell-source line PL1 to the voltage Vw, whereby the voltage Vw is applied to the first power-source terminal 207 (t3). After that, the word line WL1 is made the Vdd level (select level) (t4), and the n-channel MOS transistors 201 and 202 are turned on, whereby the nodes SN1 and SN1B are made desired values, and then the action of write is started (t5). Thus, electrons are caused to flow from the pinned layer PLY to the free layer FLY in the magnetoresistance element 203, and magnetoresistance element 203 is consequently forced to transition from the high-resistance condition (denoted by the character “H”) to the low-resistance condition (denoted by the character “L”). In the magnetoresistance element 204, electrons flowing form the free layer FLY to the pinned layer PLY force the magnetoresistance element 204 to transition from the low-resistance condition to the high-resistance condition.

Subsequently, the word line WL1 is made the Vss level, i.e. non-select level (t6), and the control circuit 18 shifts the potential of the cell-source line PL1 to the Vdd level (t7). The period from the time t5 to t6 corresponds to a write period 701 for writing. The bit lines BL1 and BL1B are thereafter made the Vdd levels (t8) and the R/W signal is turned back to High level (t9). Then, the overwrite on the magnetoresistance memory cell MC is completed.

It is desired that in such overwrite procedure, the potential of a word line that is not targeted for overwrite, i.e. non-select word line, is kept at the Vss level to prevent the potential of a selected bit line from affecting a cell on the non-select word line. Further, it is desired that the potential of a bit line belonging to a bit which is not targeted for overwrite, i.e. a non-select bit, in spite of being located on a word line targeted for overwrite, i.e. a select word line, is kept at the level Vw or Vdd, or suspended in voltage supply. Especially, when keeping such bit line at the level Vw, a current flowing through a resistance located on a select word line, but belonging to a non-select bit can be prevented, and the change in resistance of a non-select bit owing to overwrite can be hindered. In the overwrite procedure, data of a bit not targeted for overwrite remains latched in SRAM, and data of a bit to be overwritten will be latched at the time of completion of the overwrite. Therefore, no data is lost owing to the overwrite.

The example of Vw>Vdd is taken in the description here. However, the high-potential side power source voltage Vdd may be applied to the cell-source line PL1, and a voltage of 2Vdd to the bit line BL1B.

From a more qualitative standpoint, the minimum requirement is that the following relation holds among the voltages: the voltage of a bit line BL1B (i.e. a bit line connected through a MOS transistor to a storage node higher in level)>the voltage of a cell-source line PL1>the voltage of a bit line BL1 (i.e. a bit line connected through a MOS transistor to a storage node lower in level).

The closer the voltage between the bit line BL1B and cell-source line PL1 is to the voltage between the cell-source line PL1 and bit line BL1, the more readily the margin of an action can be secured with a write at any of High and Low levels.

Therefore, at the time of write, half of Vdd, i.e. Vdd/2, may be applied to the cell-source line, and the voltage Vdd may be applied to a bit line connected with the higher-level storage node through a MOS transistor.

Further, in the example, it is assumed that the source voltage of Vdd is fed from the outside, which is the same as the source voltage at the time of data holding. However, the voltage at the time of data holding may be lower than the voltage Vdd, and the voltage at the time of write may be the voltage Vdd or higher than the voltage at the time of data holding.

A conceivable means for actualizing this specifically includes lowering a voltage fed from the outside, to use the voltage thus lowered as a source voltage at the time of data holding, and using the voltage from the outside at the time of write.

Making the arrangement like this eliminates the need for generating a voltage higher than that supplied from the outside.

Now, it is noted that the relation among the write voltage Vw, source voltage Vdd and bit line voltage, and the concept of lowering a voltage from the outside can appropriately apply in embodiments which will be described later.

### <<Write Action 2 on the 4-Transistor and 2-Magnetoresistance Cell>>

Next, another procedure for overwriting the magnetoresistance memory cell MC shown in FIG. 5 will be described.

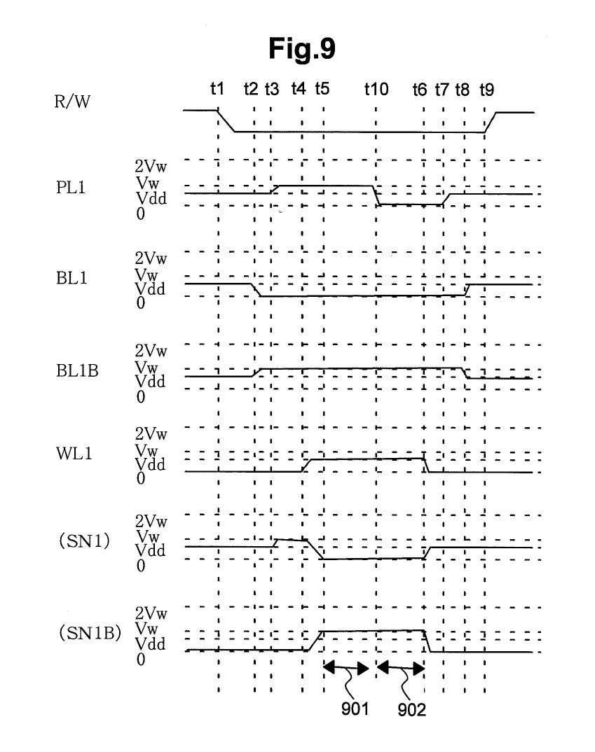

FIG. 9 shows the action timing in staple portions in overwrite on the magnetoresistance memory cell MC shown in FIG. 5.

For convenience of description, it is assumed as a condition before overwrite that the magnetoresistance element 203 is in the antiparallel state (high-resistance condition), and the magnetoresistance element 204 stays in the parallel state (low-resistance condition).

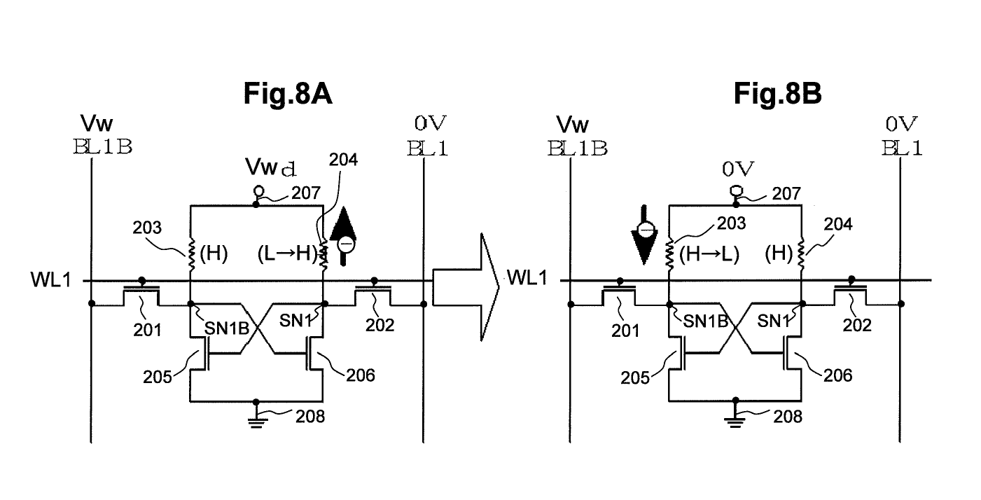

Overwrite is directed by turning the read/write signal R/W to Low level (t1). Then, as shown in FIG. 8A, the bit line BL1 is made to transition from the Vdd level to the Vss level (0-volt level), and the bit line BL1B is forced to transition from the Vdd level to the Vw level (t2). The control circuit 18 thereafter turns the potential of the cell-source line PL1 to the voltage Vw, whereby the voltage Vw is applied to the first power-source terminal 207 (t3). After that, the word line WL1 is made the Vdd level (select level) (t4), and the n-channel MOS transistors 201 and 202 are turned on. In this condition, electrons are forced to pass through the magnetoresistance element 204 connected to the node SN1, whereby a write on the magnetoresistance element 204 is started (t5).

Subsequently, the control circuit 18 turns the potential of the cell-source line PL1 to the Vss level, whereby the first power-source terminal 207 is made the Vss level as shown in FIG. 8B. Thus, electrons are made to pass through the magnetoresistance element 203 connected with the node SN1B, whereby a write on the magnetoresistance element 203 is started (t10). Herein, the period from the time t5 to t10 corresponds to a first write period 901, and the period from the time t10 to t6 corresponds to a second write period 902.

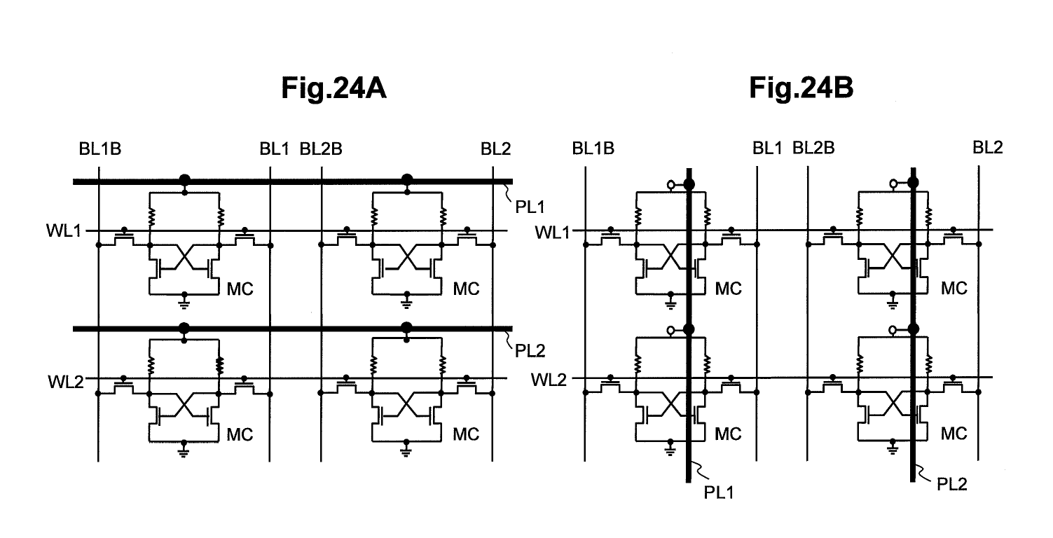

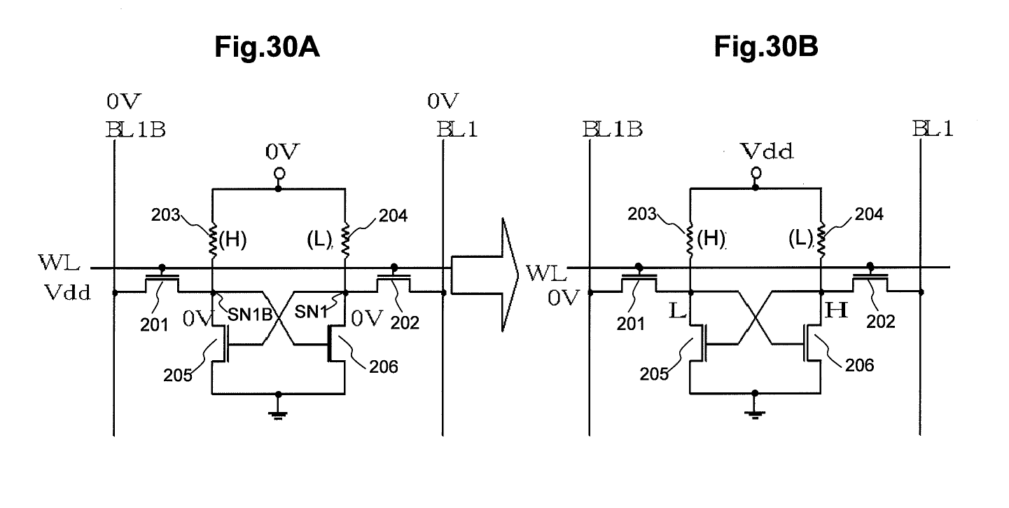

Next, the word line WL1 is turned to the Vss level, i.e. non-select level (t6). Thereafter, the control circuit 18 turns the potential of the cell-source line PL1 to the Vdd level (t7). Then the bit lines BL1 and BL1B are changed to the Vdd level, and the R/W signal is turned back to High level (t9). Thus, the overwrite on the magnetoresistance memory cell MC is completed. As to the overwrite procedure, it is desired that the potential of a word line that is not targeted for overwrite, i.e. non-select word line, is kept at the Vss level to prevent the potential of a selected bit line from affecting a cell on the non-select word line. Further, it is desired that the potential of a bit line belonging to a bit which is not targeted for overwrite, i.e. a non-select bit, in spite of being located on a word line targeted for overwrite, i.e. a select word line, is kept at the level Vw or Vdd, or suspended in voltage supply until the time t10 shown in FIG. 9. Particularly, it is desired that such bit line potential is kept at the level Vw. In addition, it is desired that after the time t10, such bit line potential is kept at the level Vss or suspended in voltage supply. Particularly, it is desired that such bit line potential is kept at the voltage level Vss. When selecting the voltage, a current flowing through a resistance of a non-select bit on the select word line can be prevented, and the change in resistance of a non-select bit owing to overwrite can be hindered. In the overwrite procedure, data of a bit not targeted for overwrite is made less prone to be latched on condition that the voltage of the first power-source terminal is at the Vss level. On this account, it is desired to refresh the data of bits which share the first power-source terminal according to the procedure shown by FIGS. 30A and 30B. Specifically, first, the potentials of the first power-source terminal and bit lines BL1 and BL1B of a target cell are made the Vss level, and the potential of the word line WL is made the Vdd level, as shown in FIG. 30A, whereby the potentials of the storage nodes are both brought to the Vss level. Second, the potential of the word line WL is made the Vss level, and the potential of the first power-source terminal is made the Vdd level, as shown in FIG. 30B, whereby data stored by the magnetoresistances can be latched. Although no special restriction is intended, it is desired in view of the shift of the memory cell to Read standby after the sequence of steps, that the potentials of the bit lines BL1 and BL1B at this point are made the Vdd level. If the first power-source terminals are arranged separately in word lines or bit lines as shown in FIGS. 24A and 24B, it is sufficient to target only the word or bit line subjected to overwrite for refresh.

As described above, the voltage level of the first power-source terminal 207 may be changed so that the resistance of one magnetoresistance element is changed and then the resistance of the other magnetoresistance element is varied.

According to the above description, the level of the storage node is changed from Low to High before changing the level of the storage node from High to Low. However, the order may be reversed.

While the example of Vw>Vdd has been shown with reference to FIG. 9, Vw=Vdd is also possible.

Further, the example in which the voltage level of the first power-source terminal 207 is made the same as that of the relevant bit line has been described. However, for the purpose of changing the magnetoresistance of one storage node, it is sufficient to make the voltage level of the first power-source terminal 207 closer to the voltage level of the bit line coupled to the one storage node in comparison to the voltage level of a bit line coupled to the other storage node.

Likewise, for the purpose of changing the magnetoresistance of the other storage node, it is sufficient to make the voltage level of the first power-source terminal 207 closer to the voltage level of the bit line coupled to the other storage node in comparison to the voltage level of the bit line coupled to the one storage node.

### <<Read Action on the 4-Transistor and 2-Magnetoresistance Cell>>

Next, a procedure for reading from the magnetoresistance memory cell MC shown in FIG. 5 will be described.

For convenience of description, it is assumed as a condition of the memory cell that the magnetoresistance element 203 is in the antiparallel state (high-resistance condition), and the magnetoresistance element 204 stays in the parallel state (low-resistance condition). In other words, the storage node SN1 is at High level, and the storage node SN1B is at Low level.

Readout is directed by turning the read/write signal R/W to High level. The bit lines BL1 and BL1B have been pre-charged to the Vdd level.

The potential of the cell-source line PL1 is at the voltage level Vdd. When the word line WL1 is made the Vdd level, i.e. select level, the n-channel MOS transistors 201 and 202 are turned on.

Substantially no current flows between the bit line BL1 and node SN1 because the node SN1 stays at High level.

However, the other node SN1B is at Low level, and therefore

current flows from the bit line BL1B into the node SN1B, and goes through the transistor 205 and to the ground-voltage line 208.

As a result, the voltage of the bit line BL1B drops. Then, a comparison between the bit line BL1 and bit line BL1B in voltage using the sense amplifier 19, and data is output.

After completion of the readout, the word line WL1 is made the Vss level, i.e. non-select level.

In the read action, the voltages of the storage nodes are unchanged substantially and therefore, no damage is caused to data.

### <<Reversal of Free and Pinned Layers' Connection Layout>>

In the above description has been shown the example in which the pinned layer is connected to the first power-source terminal in order to prevent data from being inverted with the data remaining held.

However, if greater importance is put on preventing the inversion of data owing to a current flowing at the time of latching data after the power-on, it is desired to connect the pinned layer to the MOS transistor.

### Advantage of the First Embodiment

The first embodiment brings about the following advantages.

(1) As the semiconductor memory device functions as SRAM while being supplied with power, it can hold data written therein. Further, as data is stored by the magnetoresistance elements 203 and 204, the data can be held even after the power has been cut off.

(2) With a 1Tr-1R type memory element, for example, read voltage and current are restricted depending on the overwrite properties of the resistance because of current flowing through the resistance at the time of reading, and data would be inverted depending on conditions. In addition, as the read current is controlled, in rate, by the resistance element and the series resistance of the MOS transistor, a 1Tr-1R type memory element is unsuitable for a high-speed operation. In contrast, with a semiconductor memory device which adopts the magnetoresistance memory cell MC as shown in FIG. 1, current hardly flows through the magnetoresistance elements at the time of reading, and the n-channel MOS transistors 205 and 206 cover this. Therefore, the read action never causes the inversion of data. In addition, even if an abnormal bit (retention) which can change the magnetoresistance elements takes place while the memory device is left, data is never damaged unless the two magnetoresistances are reversed. Therefore, the data stability is secured.

(3) The semiconductor memory device is easier to overwrite, and therefore the convenience as SRAM has is never lost.

(4) The magnetoresistance element 203 has the free layer connected to the n-channel MOS transistor 205, and the pinned layer connected to the first power-source terminal 207. The magnetoresistance element 204 has the free layer connected to the n-channel MOS transistor 206, and the pinned layer connected to the first power-source terminal 207. By making connections like this, stored data in the magnetoresistance memory cell MC shown in FIG. 5 on Standby can be stabilized.

### Second Embodiment

### 6-Transistor and 2-Magnetoresistance Cell

Next, another example of the structure of the magnetoresistance memory cell MC used in the semiconductor memory device shown in FIG. 1 will be described.

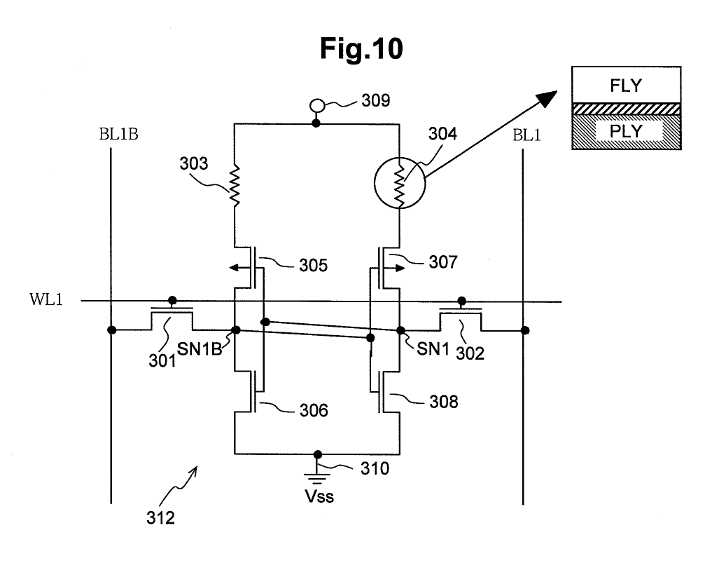

The magnetoresistance memory cell MC is of a 6Tr-2R type, and includes six transistors 305 to 308 and two magnetoresistance elements 303 and 304, as shown in FIG. 10. In the magnetoresistance memory cell MC, the p-channel MOS transistor 305 is connected with the n-channel MOS transistor 306 in series, and the p-channel MOS transistor 307 is connected with the n-channel MOS transistor 308 in series. The series-connection node SN1B between the p-channel MOS transistor 305 and n-channel MOS transistor 306 is coupled to the gate electrode (control terminal) of the p-channel MOS transistor 307 and n-channel MOS transistor 308. The series-connection node SN1 between the p-channel MOS transistor 307 and n-channel MOS transistor 308 is coupled to the gate electrode (control terminal) of the p-channel MOS transistor 305 and n-channel MOS transistor 306, whereby a latch circuit 312 is formed. The source electrode of the p-channel MOS transistor 305 is coupled to the first power-source terminal 309 through the magnetoresistance element 303. The source electrode of the p-channel MOS transistor 307 is coupled to the first power-source terminal 309 through the magnetoresistance element 304. The source electrodes of the n-channel MOS transistors 306 and 308 are coupled to the second power-source terminal 310. The second power-source terminal 310 is made the Vss level (0-volt level) of the low-potential side power source. The series-connection node SN1B between the p-channel MOS transistor 305 and n-channel MOS transistor 306 is coupled to the bit line BL1B through the n-channel MOS transistor 301. The series-connection node SN1 between the p-channel MOS transistor 307 and n-channel MOS transistor 308 is coupled to the bit line BL1 through the n-channel MOS transistor 302.

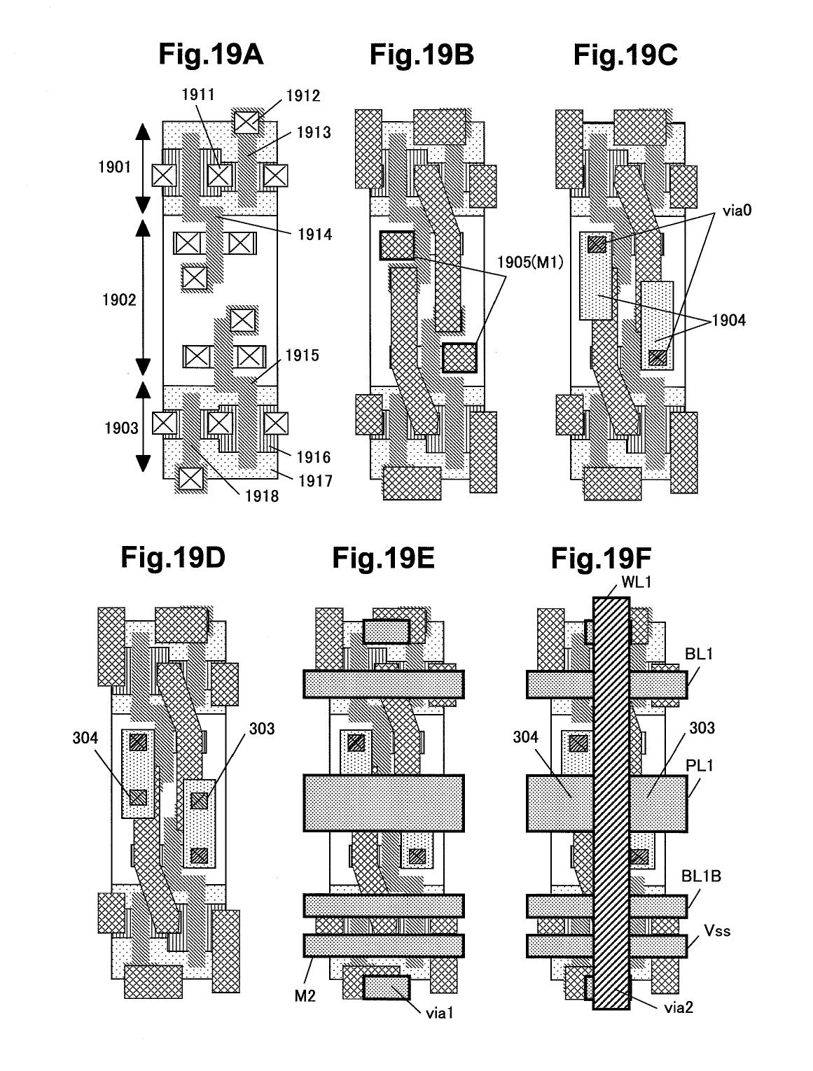

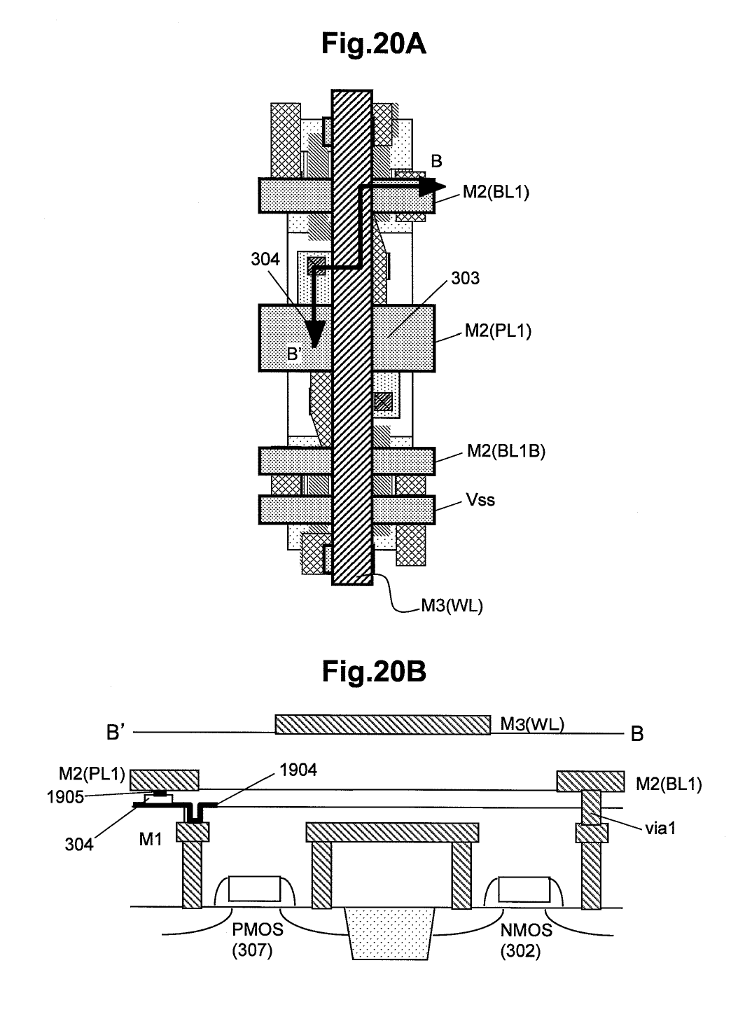

FIGS. 19A to 19F, and 20A show layouts of the magnetoresistance memory cell MC shown in FIG. 10. FIG. 20B presents a sectional view of the magnetoresistance memory cell MC taken along the line B-B′ of FIG. 20A.

Specifically, FIG. 19A presents a layout at the point of the completion of formation of contact holes CONT for connecting between a semiconductor region of the magnetoresistance memory cell MC and a first-layer metal line (M1). The region disposed in the central portion of the memory cell shown in FIG. 19A is a PMOS region 1902; the regions located separately above and below the PMOS region are NMOS regions 1901 and 1903. The PMOS region is one of features of the memory cell. The reference numeral 1911 denotes a contact hole for connecting between an active region and a first-layer metal line. The numeral 1912 denotes a contact hole for connecting between a gate electrode and the first-layer metal line. The numeral 1913 denotes the gate electrode of the n-channel MOS transistor 302. The numeral 1914 denotes the gate electrode of the MOS transistors 307 and 308. The numeral 1915 denotes the gate electrode of the MOS transistors 305 and 306. The numeral 1916 denotes an active region. The numeral 1917 denotes a separating region. The numeral 1918 denotes the gate electrode of the MOS transistor 301.

In regard to a typical SRAM, of diffusion layers of PMOS, the one which is connected to the high-potential power source Vdd is shared with PMOS of a neighboring bit. However, in this embodiment, such sharing is not performed, and an electrode which will making a part of a magnetoresistance is formed on it as shown in FIG. 19C.

FIG. 19B presents a layout at the point of the completion of formation of the first-layer metal line (M1). In this stage, two wiring lines 1905, which are to be connected to magnetoresistances, are arranged in each cell, which are electrically insulated from a neighboring cell.

FIG. 19C presents a layout at the point of the completion of formation of the lower electrode 1904 of each magnetoresistance, and a via hole (through-hole) Via0 provided therefor. Specifically, after having covered the first metal line M1 with an isolation film, the opening of the via hole Via0 is formed. Then, the lower electrode 1904 of each magnetoresistance is formed by sputtering a bulk of metal containing e.g. tantalum (Ta). Thus, the substrate of the layout as shown in FIG. 19C is prepared. After that, the magnetoresistances and upper electrodes thereof are formed by a sputtering or oxidization technique. The resultant layer formed by sputtering or oxidization is machined into a mesa form so that the magnetoresistance material and the upper electrode material are left only in the locations 303 and 304 as shown in FIG. 19D. Then, the substrate thus prepared is planarized by an isolation film.

Subsequently, first via holes are formed in the first metal line which will be connected to a bit line and a word line, and second metal lines M2 which will make bit lines BL1 and BL1B and a cell-source line PL1 are formed as shown in FIG. 19E. At the point, the upper electrode of a magnetoresistive portion is connected to the cell-source line PL1. FIG. 19F shows a layout at the point of the completion of formation of the third-layer metal line (M3). While the way of machining a magnetoresistive portion into a mesa form has been shown here as an example of the method of preparing a magnetoresistive portion, the method of preparing a magnetoresistive portion is not particularly limited so.

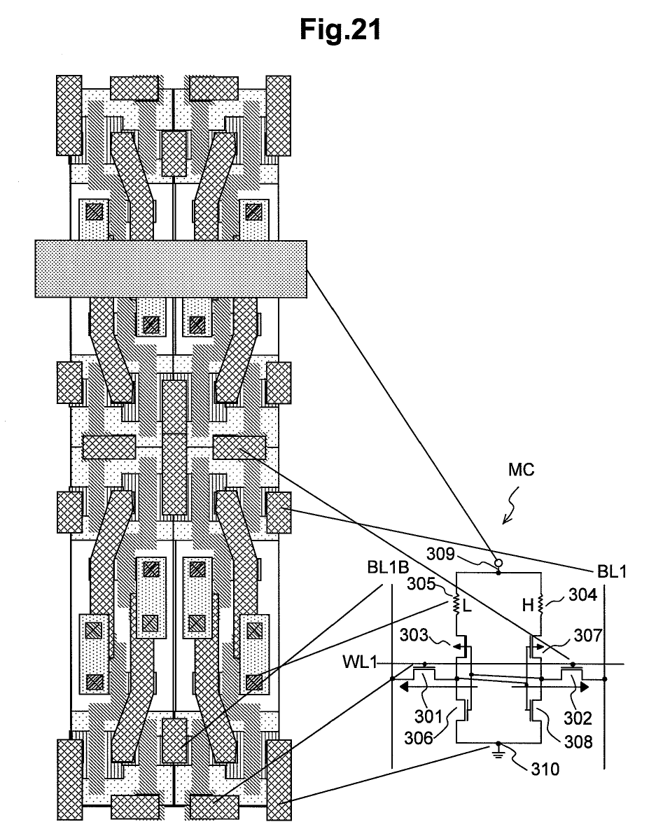

FIG. 20B shows a section of a staple portion of the memory cell taken along the line B-B′ of FIG. 20A. With reference to FIG. 21, correspondences between the magnetoresistance memory cell MC shown in FIG. 10, and the layouts shown in FIGS. 19A-19F and FIGS. 20A and 20B.

The metal lines belonging to different layers are coupled to each other through the via hole Via1 or Via2. The magnetoresistance element 304 is coupled to the first-layer metal line M1 through the via hole Via0, and further coupled to the diffusion layer of the p-channel MOS transistor 307 through the first-layer metal line M1 and the contact hole CONT. Likewise, the magnetoresistance element 303 is coupled to the first-layer metal line M1 through the via hole Via0, and further coupled to the diffusion layer of the p-channel MOS transistor 305 through the first-layer metal line M1 and contact hole CONT. However, this is not shown in the drawing.

Now, it is noted that the source electrodes of the p-channel MOS transistors 305 and 307 are coupled to the first power-source terminal 309 (cell-source line PL1) through the respective magnetoresistance elements 303 and 304, and therefore the diffusion layers of the p-channel MOS transistors 305 and 307 are not connected in common. In other words, the p-channel MOS transistors 305 and 307 are next to each other, however their diffusion layers are separated from each other. As the diffusion layers are separated in this way, the source electrodes of the p-channel MOS transistors 305 and 307 can be provided to correspond to the magnetoresistance elements 303 and 304 respectively.

### <<Relation of Interconnections in the 6-Transistor and 2-Magnetoresistance Cell, and Data Holding>>

As in the case of the magnetoresistance memory cell shown in FIG. 5, the magnetoresistance elements 303 and 304 each include a free layer which can be changed in spin orientation therein, and a pinned layer which is fixed in spin orientation therein. In this example, the magnetoresistance element 303 is coupled to the first power-source terminal at the free layer, and to the p-channel MOS transistor 303 at the pinned layer. The magnetoresistance element 304 is coupled to the first power-source terminal 309 at the free layer and to the p-channel MOS transistor 307 at the pinned layer. The reason why the magnetoresistance elements 303 and 304 are placed is as follows.

The magnetoresistance memory cell MC of 6Tr-2R type has no stationary current flowing therein on standby except a slight amount of current attributed to e.g. a current leakage from a transistor. However, in case that electrons flow through the magnetoresistance element 303 or 304 and change the condition thereof before the holding state of the latch circuit 312 is fixed by the states of the magnetoresistance elements 303 and 304 after power-on, caution is required because information cannot be held correctly.

For example, a magnetoresistance element staying in the low-resistance condition is easy to change in condition because more electrons can pass therethrough in comparison to a magnetoresistance element in the high-resistance condition.

Hence, in this embodiment, a measure to protect the condition of a magnetoresistance element in the low-resistance condition preferentially is taken. In a case where the high-potential side power source Vdd is supplied to the first power-source terminal 309 in response to power-on, it is expected that electrons will flow from the p-channel MOS transistors 305 and 307 toward the first power-source terminal 309. Therefore, it is adequate to arrange the memory cell so that such electrons' flow serves to maintain the parallel state of the magnetoresistance element staying in the low-resistance condition.

To keep the parallel state of the magnetoresistance element, it is necessary to force electrons to flow from the pinned layer toward the free layer (see FIG. 3D). Therefore, the magnetoresistance elements 303 and 304 must be laid out so that the pinned layers thereof are connected to the p-channel MOS transistors 305 and 307.

In the magnetoresistance element in the high-resistance condition, electrons flow from the pinned layer toward the free layer, which works to cause the transition of the magnetoresistance element from the antiparallel state (high-resistance condition) to the parallel state (low-resistance condition). However, only a small amount of electrons flow in the magnetoresistance element because the magnetoresistance element stays in the high-resistance condition, and from the fact, it is expected that such small amount of electrons has little effect on the transition of the magnetoresistance element.

### <<Write Action 1 on the 6-Transistor and 2-Magnetoresistance Cell>>

Now, a procedure for overwriting the magnetoresistance memory cell MC shown in FIG. 10 will be described.

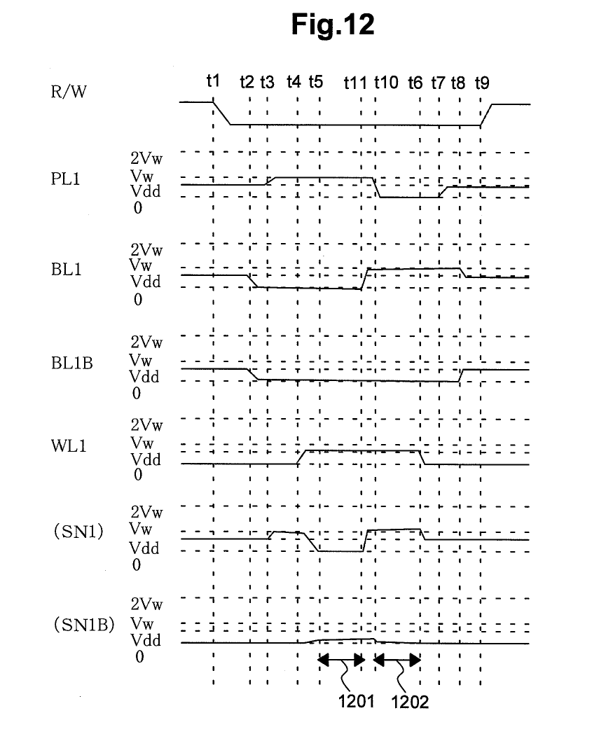

FIG. 12 shows the action timing in staple portions during overwrite on the magnetoresistance memory cell MC shown in FIG. 10.

For convenience of description, it is assumed as a condition before overwrite that the magnetoresistance element 303 in the antiparallel state (high-resistance condition), and the magnetoresistance 304 stays in the parallel state (low-resistance condition).

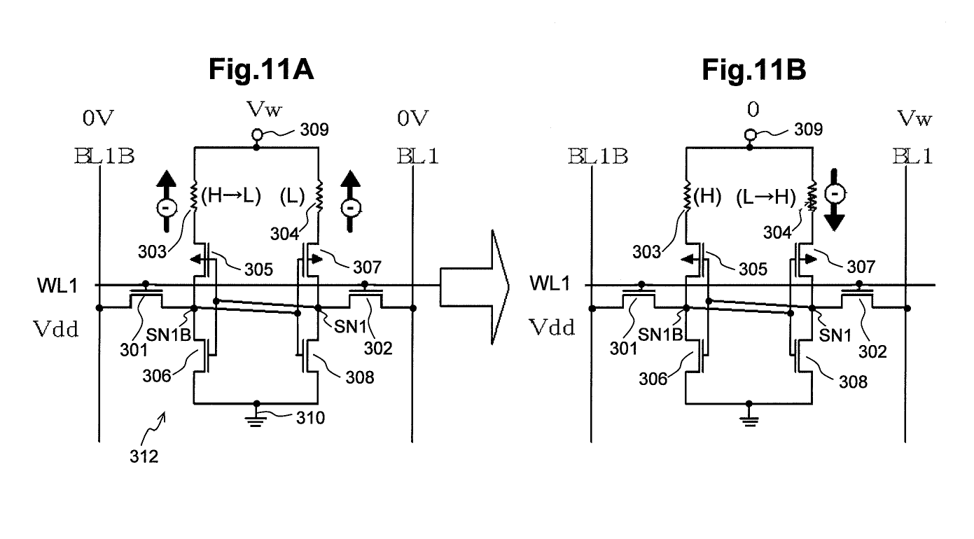

Overwrite is directed by turning the read/write signal R/W to Low level (t1). Then, as shown in FIG. 11A, the bit line BL1 is made to transition from the Vdd level to Vss level (0-volt level), and the bit line BL1B is made to transition from the Vdd level to the Vss level (0-volt level) (t2). The control circuit 18 thereafter turns the potential of the cell-source line PL1 to the voltage Vw, whereby the voltage Vw is applied to the first power-source terminal 309 (t3). After that, the word line WL1 is made the Vdd level (select level) (t4), and the n-channel MOS transistors 301 and 302 are turned on. Thus, electrons flow in the same direction in the magnetoresistance elements 303 and 304, whereby the resistance conditions thereof are made comparable to each other (t5).

Next, as shown in FIG. 11B, a bit line (BL1 in this example) to which the magnetoresistance targeted for change in resistance condition is connected is made the Vw level (t11), and the cell-source line PL1 is forced to transition to the Vss level (0-volt level) (t10), whereby the first power-source terminal 309 is made the Vss level (0-volt level). Consequently, the node SN1 is made the Vw level, and electrons flow from the free layer FLY toward the pinned layer PLY in the magnetoresistance element 304, whereby a write on the magnetoresistance element 304 is performed. As a result of the write, the magnetoresistance element 304 is forced to transition from the low-resistance condition to the high-resistance condition. Herein, the period from the time t5 to t11 corresponds to a first write period 1201, and the period from the time t10 to t6 corresponds to a second write period 1202.

Thereafter, the word line WL1 is made the Vss level, i.e. non-select level (t6). Then, the control circuit 18 turns the potential of the cell-source line PL1 to the Vdd level (t7). Further, the bit lines BL1 and BL1B are made the Vdd level (t8), and the R/W signal is turned back to High level (t9). Then, an overwrite on the magnetoresistance memory cell MC is completed.

In other words, the two magnetoresistances are both put in one of the high-resistance condition and low-resistance condition of a lower resistance value, and then the resistance condition of one magnetoresistance is changed.

In the above example, the two magnetoresistances are both brought to the low-resistance condition, and then one magnetoresistance is put in the high-resistance condition.

Alternatively, a procedure in which the two magnetoresistances are placed in the high-resistance condition, and then one magnetoresistance is brought to the low-resistance condition.

Incidentally, the voltage Vdd may be equal to V_{W} as already noted in the description of the first embodiment.

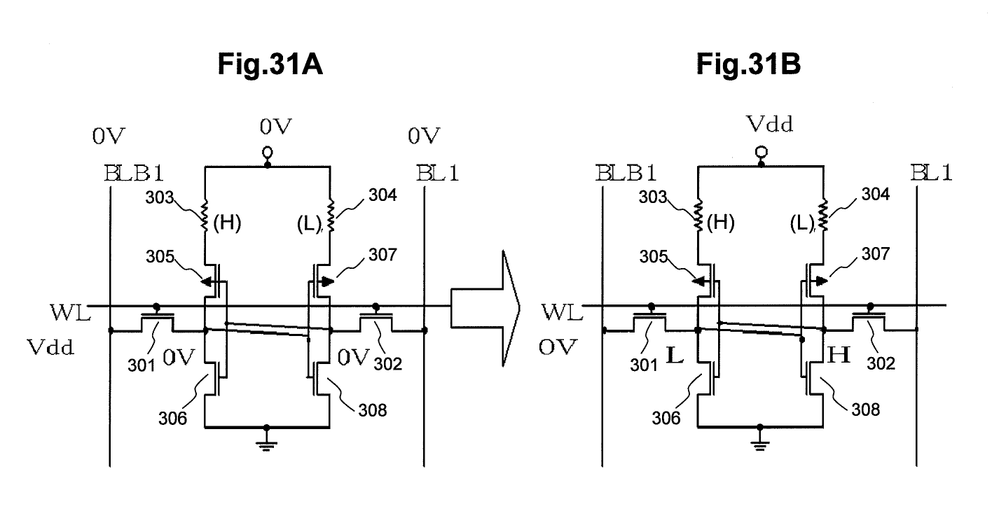

As to the overwrite procedure, it is desired that the potential of a word line that is not targeted for overwrite, i.e. non-select word line, is kept at the Vss level to prevent the potential of a selected bit line from affecting a cell on the non-select word line. Further, it is desired that the potential of a bit line belonging to a bit which is not targeted for overwrite, i.e. a non-select bit, in spite of being located on a word line targeted for overwrite, i.e. a select word line, is kept at the level Vw or Vdd, or suspended in voltage supply until the time t10 shown in FIG. 12. Particularly, it is desired that such bit line potential is kept at the level Vw. In addition, it is desired that after the time t10, such bit line potential is kept at the level Vss or suspended in voltage supply. Particularly, it is desired that such bit line potential is kept at the voltage level Vss. When selecting the voltage, a current flowing through a magnetoresistance of a non-select bit on a select word line can be prevented, and the change in resistance of a non-select bit owing to overwrite can be hindered. In the overwrite procedure, data of a bit not targeted for overwrite is never latched on condition that the voltage of the first power-source terminal is at the Vss level. Further, inverted data with respect to data recorded by the magnetoresistances is latched in a bit subjected to overwrite. Therefore, all the data of bits which share the first power-source terminal need to be refreshed according to the procedure shown by FIGS. 31A and 31B. Specifically, first, the potentials of the first power-source terminal and bit lines BL1 and BL1B of a target cell are made the Vss level, and the potential of the word line WL is made the Vdd level, as shown in FIG. 31A, whereby the potentials of the storage nodes are both brought to the Vss level. Second, the potential of the word line WL is made the Vss level, and the potential of the first power-source terminal is made the Vdd level, as shown in FIG. 31B, whereby data stored by the magnetoresistances can be latched. Although no special restriction is intended, it is desired in view of the shift of the memory cell to Read standby after the sequence of steps, that the potentials of the bit lines BL1 and BL1B at this point are made the Vdd level. If the first power-source terminals are arranged separately in word lines or bit lines as shown in FIGS. 24A and 24B, it is sufficient to target only the word or bit line subjected to overwrite for refresh.

### <<Write Action 2 on the 6-Transistor and 2-Magnetoresistance Cell>>

Next, another procedure for overwriting the magnetoresistance memory cell MC shown in FIG. 10 will be described.

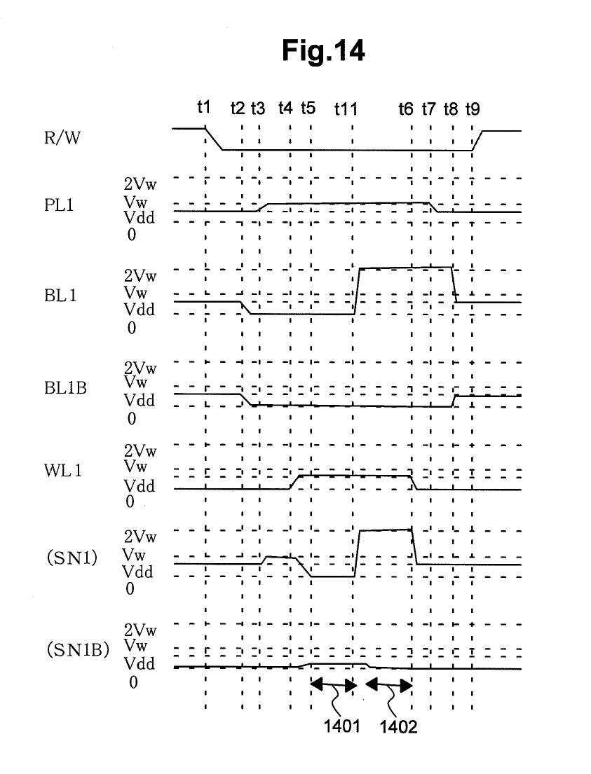

FIG. 14 shows the action timing in staple portions during overwrite on the magnetoresistance memory cell MC shown in FIG. 10.

For convenience of description, it is assumed as a condition before overwrite that the magnetoresistance element 303 in the antiparallel state (high-resistance condition), and the magnetoresistance 304 stays in the parallel state (low-resistance condition).

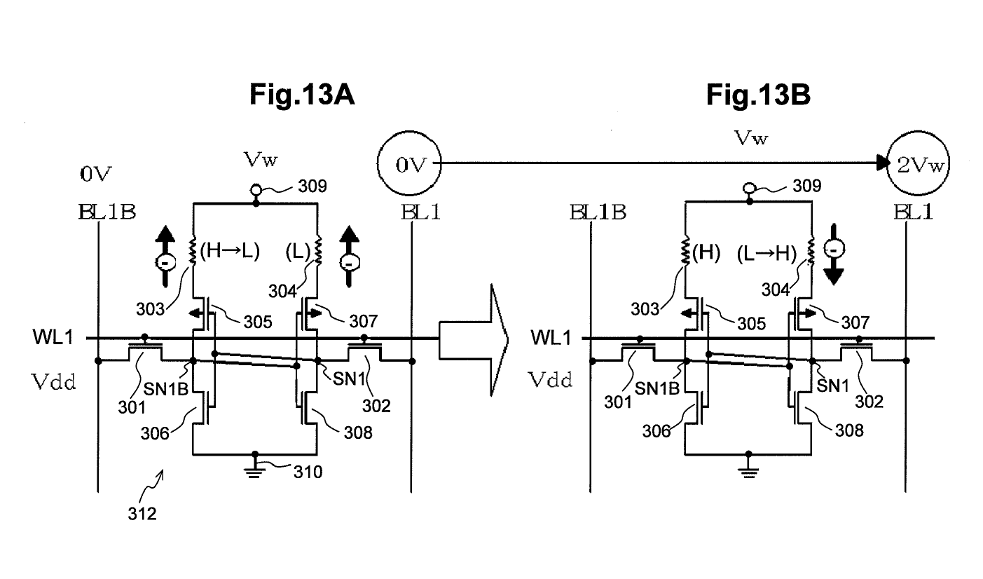

Overwrite is directed by turning the read/write signal R/W to Low level (t1). Then, as shown in FIG. 13A, the bit line BL1 is made to transition from the Vdd level to Vss level (0-volt level), and the bit line BL1B is made to transition from the Vdd level to the Vss level (0-volt level) (t2). The control circuit 18 thereafter turns the potential of the cell-source line PL1 to the voltage Vw, whereby the voltage Vw is applied to the first power-source terminal 309 (t3). Further, the word line WL1 is made the Vdd level (select level) (t4), and the n-channel MOS transistors 301 and 302 are turned on. Thus, electrons flow in the same direction in the magnetoresistance elements 303 and 304, whereby the resistance conditions thereof are made comparable to each other (t5).

Next, as shown in FIG. 13B, a bit line (BL1 in this example) to which the magnetoresistance targeted for change in resistance condition is connected is made the 2Vw level (t11). At this point, the cell-source line PL1 is at the Vw level, and the first power-source terminal 309 is at the Vw level. Therefore, electrons flows from the free layer toward the pinned layer in the magnetoresistance element 304, and thus a write on the magnetoresistance element 304 is performed. As a result of the write action, the magnetoresistance element 304 is forced to transition from the low-resistance condition to the high-resistance condition.

Thereafter, the word line WL1 is made the Vss level (non-select level) (t6). Then, the control circuit 18 turns the potential of the cell-source line PL1 to the Vdd level (t7). Further, the bit lines BL1 and BL1B are made the Vdd level (t8), and the R/W signal is turned back to High level (t9). Then, an overwrite on the magnetoresistance memory cell MC is completed. Herein, the period from the time t5 to t11 corresponds to a first write period 1401, and the period from the time t11 to t6 corresponds to a second write period 1402.

Incidentally, the voltage level Vw may be half of Vdd, i.e. Vdd/2, as already noted in the description of the first embodiment.

As to the overwrite procedure, it is desired that the potential of a word line that is not targeted for overwrite, i.e. non-select word line, is kept at the Vss level to prevent the potential of a selected bit line from affecting a cell on the non-select word line. Further, it is desired that the potential of a bit line belonging to a bit which is not targeted for overwrite, i.e. a non-select bit, in spite of being located on a word line targeted for overwrite, i.e. a select word line, is kept at the level Vw or Vdd, or suspended in voltage supply. Particularly, if such bit line potential is kept at the level Vw, a current flowing through a magnetoresistance of a non-select bit on a select word line can be prevented, and the change in resistance of a non-select bit owing to overwrite can be hindered. In the overwrite procedure, data of a bit not targeted for overwrite is latched, however inverted data with respect to data recorded by the magnetoresistances is latched in a bit subjected to overwrite. Therefore, it is necessary to refresh data of a bit overwritten according to the procedure shown by FIGS. 31A and 31B as described in “Write action 1 on the 6-transistor and 2-magnetoresistance cell”.

### <<Read Action on the 6-Transistor and 2-Magnetoresistance Cell>>

The action of read from the 6-transistor and 2-magnetoresistance cell is the same as that for the 4-transistor and 2-magnetoresistance cell.

### <<Startup of the 6-Transistor and 2-Magnetoresistance Cell After Power Source Cutoff>>

Next, the startup of the magnetoresistance memory cell MC shown in FIG. 10 after power source cutoff will be described.

In the case of the magnetoresistance memory cell MC of 6Tr-2R type, a latching condition in the latch circuit 312 is released on cutoff of the power source. Therefore, the latching condition in the latch circuit 312 is restored based on the conditions of the magnetoresistance elements 303 and 304 at the time of the next power-on.

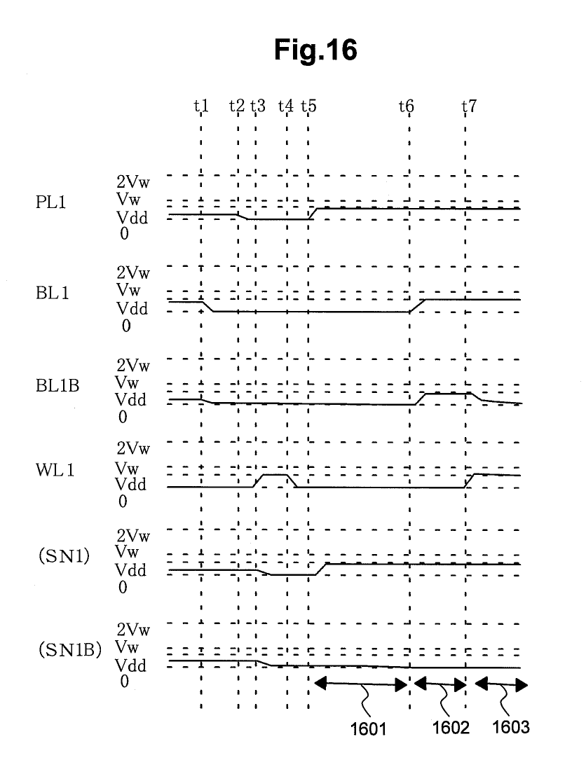

FIG. 16 shows the action timing in startup of the magnetoresistance memory cell MC shown in FIG. 10 after power source cutoff.

To avoid a middle potential, the bit lines BL1 and BL1B are brought to the potential level (0-volt level) of the low-potential side power source Vss (t1), and the cell-source line PL1 is made the Vss level (t2). Then, the word line WL1 is made the level of the high-potential side power source Vdd, and the n-channel MOS transistors 301 and 302 are turned on, whereby the potentials of the nodes SN1 and SN1B are both changed to 0 volt.

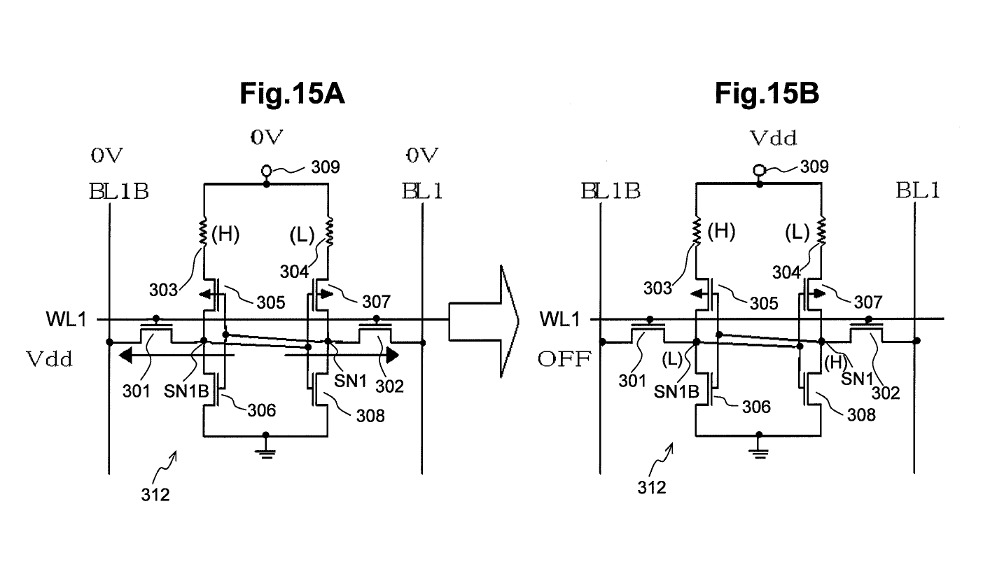

Next, as shown in FIG. 15B, the word line WL1 is made the potential level (0-volt level) of the low-potential side power source Vss (t4), and the cell-source line PL1 is turned to the potential level of the high-potential side power source Vdd, whereby the high-potential side power source Vdd is supplied to the first power-source terminal 309 (t5). In this condition, the logic of the nodes SN1 and SN1B is decided by the difference in resistance between the magnetoresistance elements 303 and 304, and the logic levels are latched by the latch circuit 312 (t5). Then, the startup of the magnetoresistance memory cell MC after power source cutoff is completed. After that, stored data can be read on an as-needed basis (t6, t7). Herein, the period from the time t5 to t6 corresponds to a data-latching period 1601, the period from the time t6 to t7 corresponds to a read-preparatory period 1602, and the time after t7 corresponds to a read period 1603.

The method of restoring data memorized by a magnetoresistance in the memory cell has been described here as a startup sequence after power source cutoff. However, the data-restoring method is not limited, in application, to the case that the power source has been cut off, and it can be leveraged as a means for restoring data and a means for increasing the reliability thereof.

The data-restoring method can be leveraged as a means for correcting a previously uncorrectable error in a semiconductor device, which can detect and correct an error in data, which has been held, e.g. in case that the data is inverted owing to a soft error or the like. Further, in a case where data is held by use of a parity code, for example, one bit of error can be sensed, but it can not be corrected. In a case where data is held by use of a hamming code which enables the correction of an error up to N bits, an error of N+1 bits or larger can be sensed, but it cannot be corrected.

However, as data can be recovered from the resistance value of each magnetoresistance again, even an uncorrectable error can be corrected by use of an existing error-correcting code as long as it can be detected.

Therefore, a highly reliable semiconductor device can be constructed. Because such data recovery is performed, the data-restoring method can be also used as a means for refreshing data by resetting data latched at a storage node at one point, and then newly re-latching the data held by a magnetoresistance.

The method for starting up the memory cell according to the second embodiment after power source cutoff has been described here. However, the action steps thereof can be applied to the memory cell according to the first embodiment.

### <<Reversal of Free and Pinned Layers' Connection Layout>>

In the above description has been shown the example in which the pinned layer PLY is connected to the MOS transistor in order to prevent data from being inverted owing to a current flowing when data is latched in the memory cell after power-on.

However, a way including the steps of providing a voltage of the Vdd potential from bit lines to storage nodes in the cell, and after power-on, bringing the voltage of one node close to the second power-source level is possible as a power-on sequence.

In this case, it is preferable to connect the pinned layer to the first power-source terminal.

### Advantage of the Second Embodiment

The second embodiment brings about the following advantages.

(1) As the semiconductor memory device functions as SRAM while being supplied with power, it can hold data written therein. Further, as data is stored by the magnetoresistance elements 303 and 304, the data can be held even after the power has been cut off.

(2) With a 1Tr-1R type memory element, for example, read voltage and current are restricted depending on the overwrite properties of the resistance because of current flowing through the resistance at the time of reading, and data would be inverted depending on conditions. In addition, as the read current is controlled, in rate, by the resistance element and the series resistance of the MOS transistor, a 1Tr-1R type memory element is unsuitable for a high-speed operation. In contrast, with a semiconductor memory device which adopts the magnetoresistance memory cell MC as shown in FIG. 1, current hardly flows through the magnetoresistance elements at the time of reading, and the n-channel MOS transistors 306 and 308 cover this. Therefore, the read action never causes the inversion of data. In addition, even if an abnormal bit (retention) which can change the magnetoresistance elements takes place while the memory device is left, data is never damaged unless the two magnetoresistances are reversed. Therefore, the data stability is secured.

(3) The semiconductor memory device is easier to overwrite, and therefore the convenience as SRAM has is never lost.

(4) The magnetoresistance element 303 has the pinned layer connected to the n-channel MOS transistor 306, and the free layer connected to the first power-source terminal 309. The magnetoresistance element 304 has the pinned layer connected to the n-channel MOS transistor 308, and the free layer connected to the first power-source terminal 309. By making connections like this, stored data in the magnetoresistance memory cell MC shown in FIG. 10 on Standby can be stabilized.

### Third Embodiment

Next, examples of application of the semiconductor memory device 100 will be described.

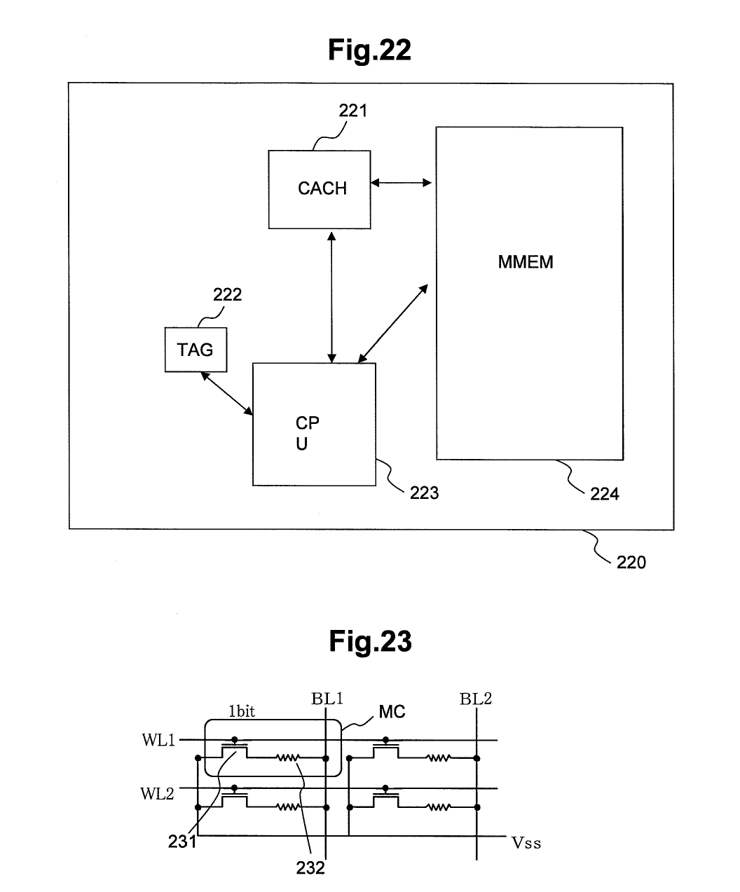

FIG. 22 shows a microcomputer as an example of the semiconductor device.

Although no special restriction is intended, the microcomputer 220 shown in FIG. 22 includes a cache memory (CACH) 221, a tag memory (TAG) 222, a central processing unit (CPU) 223, and a main memory (MMEM) 224, and is formed on a semiconductor substrate, such as a monocrystalline silicon substrate, by a well-known semiconductor IC manufacturing technique.

The CPU 223 executes a predetermined arithmetic computation following a previously set program. Various data used during an arithmetic computation by CPU 223 are stored in the main memory 224. The main memory 224 has a plurality of word lines WL1 and WL2, a plurality of bit lines BL1 and BL2, and so-called 1Tr-1R type memory cells MC placed at intersection points of word lines and bit lines, as shown in FIG. 23. Each 1Tr-1R type memory cell MC includes a magnetoresistance element 232 and an n-channel MOS transistor 231, which are connected to each other in series. The magnetoresistance element 232 includes a ferromagnetic material, in which information can be stored by changing the resistance value thereof. The main memory 224 includes a plurality of 1Tr-1R type memory cells MC, and therefore it take longer time to read therefrom in comparison to a memory device, such as the semiconductor memory device 100, including 4Tr-2R type memory cells MC or 6Tr-2R type memory cells MC. The semiconductor memory device 100 is adopted for the cache memory 221. Data used by CPU 223 at a high frequency are stocked in the cache memory 221 capable of working at a high speed. Thus, the number of accesses to the main memory 224 working at a lower speed can be reduced, and the microcomputer can be speeded up in processing. In the tag memory 222 is stored tag information which enables a judgment about whether or not target data is in the cache memory 221. The CPU 223 checks the tag information in the tag memory 222 at the time of memory access. In case that target data is judged to be in the cache memory 221, CPU 223 reads the target data therefrom. However, in case that the target data is judged not to be in the cache memory 221, CPU 223 reads the target data from the main memory 224. At the point, the data read from the main memory 224 is written into the cache memory 221 in order to prepare for a later memory access. In parallel with this, tag information in the tag memory 222 is updated.

As to the microcomputer 220 like this, the cache memory 221 is required to work at a high speed. Therefore, it is desired that the semiconductor memory device 100 which includes 4Tr-2R type memory cells MC or 6Tr-2R type memory cells MC is adopted for the cache memory 221. In contrast, with regard to the main memory 224, the storage capacity takes precedence over the access rate. Therefore, it is desired that the chip footprint of the main memory 224 is reduced by using 1Tr-1R type memory cells MC.

In the case of using SRAM for the tag memory, it is desired to adopt a memory device configured with 4Tr-2R type memory cells MC or 6Tr-2R type memory cells MC.

In the case of using CAM (Context Addressable Memory) for the tag memory, an SRAM latching part may be adopted for a cell constructed by adding additional transistors to an SRAM cell appropriately.

While the microcomputer has been described as an example here, the semiconductor memory device may be applied to a so-called SoC (System-on-a-Chip) device having multiple functions.

### Fourth Embodiment

(1) As shown in FIG. 24A, the semiconductor memory device is arranged so that cell-source lines PL1 and PL2 are provided corresponding to word lines WL1 and WL2, and only when the word line WL1 or WL2 is driven to the select level, the control circuit 18 allows supply of power source to the cells through the corresponding cell-source line PL1 or PL2. Arranging the memory device like this, supply of power source through the cell-source line corresponding to a non-select word line is never conducted. Therefore, a wasteful current consumption can be reduced in comparison to the case that power source is provided to all of first power-source terminals 207 through cell-source lines PL1 and PL2 regardless of whether the word lines are selected or not.

(2) Also, in the case of arranging the semiconductor memory device so that cell-source lines PL1 and PL2 are provided corresponding to complementary bit lines BL1 and BL1B, and BL2 and BL2B as shown in FIG. 24B, and the control circuit 18 allows supply of power source to the cell through a cell-source line corresponding to a pair of complementary bit lines fitting a column address targeted for a read or write action, a wasteful current consumption can be reduced as in the case shown in FIG. 24A.

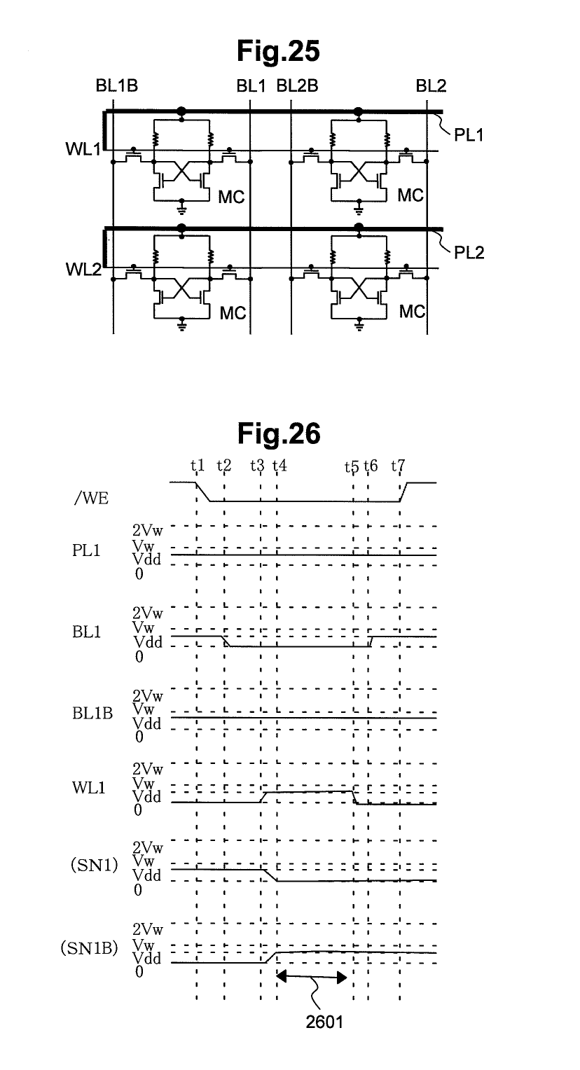

(3) Also, the semiconductor memory device may be arranged so that cell-source lines PL1 and PL2 are provided corresponding to the word lines WL1 and WL2, and the word line WL1 is coupled with the cell-source line PL1 corresponding to it, and the word line WL2 is coupled with the cell-source line PL2 corresponding to it, as shown in FIG. 25. According to such arrangement, when the word line WL1 or WL2 is driven to the select level, a voltage of the select level is supplied to the cell-source line PL1 or PL2 corresponding to the driven word line therethrough word line. Therefore, the structure of the control circuit 18 can be simplified in comparison to the case of FIG. 24A.

### Fifth Embodiment

On the semiconductor memory device 100 including 6Tr-2R type memory cells MC as shown in FIG. 10, a volatile write can be performed apart from its originally intended nonvolatile write. FIG. 26 shows the action timing in this case. The basic structure of the semiconductor memory device 100 is the same as that shown in FIG. 1. The memory cell MC is of 6Tr-2R type, which is shown in FIG. 10. Hence, actions according to the sequences as described with reference to FIGS. 12, 14 and 15 can be executed. However, in this example, a volatile write enable signal /WE is used newly as shown in FIG. 26. When the volatile write enable signal /WE is asserted into Low level, a volatile write on the 6Tr-2R type memory cell MC is performed. Specifically, the volatile write enable signal /WE is asserted into Low level (t1), and then data for write is delivered to the bit lines BL1 and BL1B (t2). For example, when the word line WL1 shown in FIG. 10 is driven to the Vdd level (select level) (t3) in this condition, the n-channel MOS transistors 301 and 302 are turned on, and the data for write delivered through the bit lines BL1 and BL1B is written on the latch circuit 312, regardless of conditions of the magnetoresistance elements 303 and 304 at this point (t4). Next, the word line WL1 is brought to the Vss level (non-select level) (t5), and then the bit lines BL1 and BL1B are both made the Vdd level (t7). Now, the period from the time t4 to t5 corresponds to a write period 2601. Since then, the condition of the latch circuit 312 will be kept as it is. However, in case that the source voltage is cut off, the condition of the latch circuit 312 is lost, and at the time of the next power-on, the logic of the nodes SN1 and SN1B is decided by the difference in resistance between the magnetoresistance elements 303 and 304, and the logic levels are latched by the latch circuit 312 following the sequence as described with reference to FIG. 16.

Hence, in the case of adopting the 6Tr-2R type memory cell MC as shown in FIG. 10, two write modes of the nonvolatile write and volatile write can be used actually. Therefore, CPU 223 will selectively use the modes as required.

### Sixth Embodiment

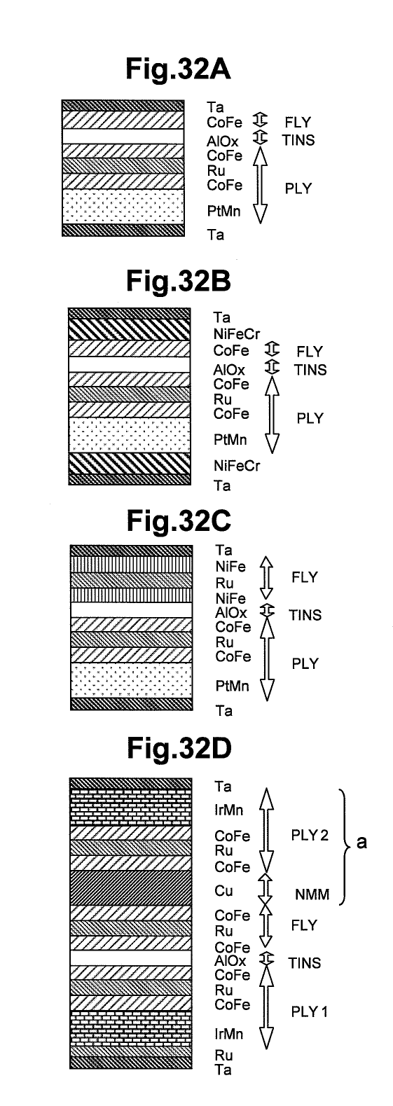

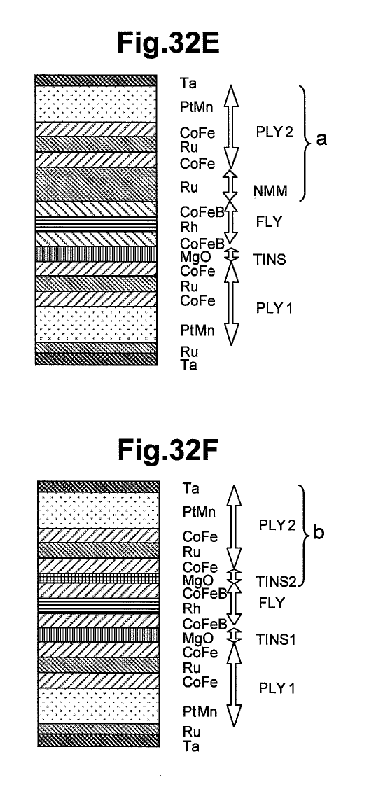

Other than a magnetoresistance element having the structure as shown in FIG. 2, ones which can be adopted as a magnetoresistance element on which the TMR effect works well includes: a magnetoresistance element which has a multilayer consisting of stacked PtMn, CoFe, Ru, CoFe, AlOx, NiFe, Ru, and NiFe films; and a magnetoresistance element which has a pair of Ta electrodes and a multilayer consisting of stacked NiFeCr, PtMn, CoFe, Ru, CoFe, AlOx, CoFe, and NiFe films between the two electrodes. Their structures are as shown in FIG. 4A. Further, specific examples of structures adoptable for magnetoresistance elements for a 6Tr-2R type memory cell will be described with reference to FIGS. 32A to 32F. In all the drawings, an electrode connected to PMOS transistor is drawn in a lower portion of each sketch, which is herein referred to as “lower electrode”. Further, in all the drawings, an electrode connected to the first power-source terminal is drawn in an upper portion of each sketch, which is herein referred to as “upper electrode”.

The magnetoresistance element shown in FIG. 32A has a Ta layer used as its lower electrode, on which the following are stacked in order: a PtMn layer as an antiferromagnetic layer; a CoFe/Ru/CoFe multilayer whose magnetizing directions are fixed by the exchange coupling with PtMn (in which the two CoFe layers are connected to each other through the Ru layer by synthetic antiferromagnetic coupling, thereby making more stable the fixing of the magnetization); an AlOx layer making a tunnel isolation layer TINS; a CoFe layer making a free layer FLY which forms a magnetic recording layer; and an upper electrode of Ta. In the magnetoresistance element, the PtMn layer and the CoFe/Ru/CoFe multilayer function as the pinned layer PLY as a whole. As the tunnel isolation layer and pinned layer are laid out on the side opposite to the first power-source terminal with respect to the free layer, the inversion of the magnetoresistance, which would be caused by a current flowing in the cell at the time of latching the difference in resistance, is prevented.

The magnetoresistance element shown in FIG. 328 is an example in which NiFe Cr films are interposed between the Ta lower electrode and PtMn layer, and between the CoFe layer making the free layer FLY and the Ta upper electrode respectively. The positional relations of the free layer FLY, tunnel isolation layer TINS and pinned layer PLY with respect to the first power-source terminal are the same as those in the case shown in FIG. 32A, and the inversion of resistance at the time of data latching is prevented by such layout. As shown in this example, an optional material may be placed between the originally intended constituent layer of the magnetoresistance element and the electrode for the purposes of increasing the adhesiveness with the electrode and securing the magnetic stability. While PtMn is used for the antiferromagnetic layer in this example, another antiferromagnetic material, such as IrMn, may be used.

The magnetoresistance element shown in FIG. 32C has the free layer FLY composed of three layers, in which two magnetic layers NiFe are connected to each other through a nonmagnetic layer Ruby synthetic antiferromagnetic coupling. In this way the magnetoresistance element is arranged to become more stable against the inversion of magnetization owing to a disturbance such as a leak magnetic field. Now, it is apparent that the positional relations of the free layer FLY, tunnel isolation layer TINS and pinned layer PLY with respect to the first power-source terminal are the same as those in the cases shown in FIGS. 32A and 32B.

The magnetoresistance element may have a structure such that a free layer is located between two pinned layers, as shown in JP-A-2007-27575, and JP-A-2001-156358. The structures shown in FIGS. 32D-32F correspond to this structure.

FIGS. 32D and 32E each show examples of the structure realized by newly adding a portion denoted by “a”, which is composed of a nonmagnetic metal layer NMM and a pinned layer PLY2, to the structure shown in FIG. 32C. The magnetoresistance elements shown in FIGS. 32D and 32E are both substantially the same as that shown in FIG. 32C in the structure between the electrode connected to PMOS transistor and the free layer FLY inclusive, except that the materials of respective constituent layers or the combination thereof are somewhat varied. The magnetoresistance elements shown in FIGS. 32D and 32E are remarkably different from that shown in FIG. 32C in the structure between the free layer FLY and the first power-source terminal. Specifically, a Cu or Ru film is stacked as the nonmagnetic metal layer NMM, first. Subsequently, a multilayer of ferromagnetic/nonmagnetic/ferromagnetic composed of three layers of CoFe, Ru and CoFe, and bonded by synthetic antiferromagnetic coupling is stacked on the nonmagnetic metal layer NMM. Further an antiferromagnetic layer of IrMn or PtMn is stacked on the CoFe/Ru/CoFe layer. The resultant layer composed of CoFe/Ru/CoFe layer with IrMn or PtMn formed thereon functions as the pinned layer PLY2 as a whole. According to the structures as shown in FIGS. 32D and 32E, the Cu or Ru layer and the pinned layer PLY2 are stacked on the free layer FLY, and therefore electrons uniformed in spin orientation, which have passed through or have been reflected by the pinned layer PLY2, will be conveyed to the free layer FLY. As a result, not only a spin torque from the bottom of the drawing, but also a spin torque from the top thereof can be caused to act on the free layer FLY, and therefore the free layer FLY can be inverted with a smaller density of current.

Further, in the examples shown in FIGS. 32D and 32E, there is no tunnel isolation layer above the free layer FLY. Therefore, the tunnel magnetoresistance is decided by the spin orientations of the free layer FLY and pinned layer PLY1 below the free layer. Now it is noted that position-related expressions, such as above, below, upper, lower, etc. are herein expressions based on the positions of parts or constituents of interest in each drawing.

According to the structures shown, as examples, in FIGS. 32D and 32E, the magnetoresistance element is arranged so that the pinned layers are disposed above and below the free layer FLY, and the tunnel isolation layer TINS is disposed on the side opposite to the first power-source terminal with respect to the free layer FLY as shown in FIG. 32A. Using such structure, the inversion of the magnetoresistance, which would be caused by a current flowing in the cell at the time of latching the difference in resistance, is prevented, as described above.

In the examples of FIGS. 32D and 32E, the antiferromagnetic materials adjacent to the upper and lower electrodes are selected to be identical to each other in each example. However, to optimally control the spin orientations in the pinned layers PLY1 and PLY2 above and below the free layer FLY, antiferromagnetic materials different from each other in Neel Temperature may be selectively used for the upper and lower pinned layers.

In the example shown in FIG. 32F, the portion denoted by the character “b” is newly provided one. As in the examples shown in FIGS. 32D and 32E, the structure shown in FIG. 32F is a result of changing a portion above the free layer FLY of the structure shown in FIG. 32C. In this case, not a nonmagnetic metal layer, but a tunnel isolation layer TINS2 is put on the free layer FLY. Subsequently, a multilayer of ferromagnetic/nonmagnetic/ferromagnetic composed of three layers of CoFe, Ru and CoFe, and bonded by synthetic antiferromagnetic coupling is stacked on the tunnel isolation layer. Further an antiferromagnetic layer of PtMn is stacked on the CoFe/Ru/CoFe layer. The resultant layer composed of CoFe/Ru/CoFe layer with PtMn formed thereon functions as the pinned layer PLY2 as a whole. In this case, the tunnel isolation layers TINS1 and TINS2 are disposed above and below the free layer FLY, whereby the resistance value of the whole magnetoresistive material can be increased. According to such structure, the effect that an erroneous inversion of the resistance value is prevented by making smaller the current forced to pass through the magnetoresistance at the time of latching the information of the magnetoresistance in the memory can be expected. In addition, a remarkable feature of the structure shown in FIG. 32F is that the erroneous inversion of magnetoresistance is prevented by making smaller the tunnel magnetoresistance of a portion located in an upper position in the drawing than that of a portion located in a lower position, provided that the comparison is made in the case of no difference in spin orientation between the two portions.

The examples shown in FIGS. 32A-32F has focused on a magnetoresistance connected in a 6Tr-2R type device structure. However, in the case of a magnetoresistance connected in a 4Tr-2R type device structure, it is required to provide a tunnel isolation layer on the side of a free layer closer to the first power-source terminal. Therefore, while not shown specifically, the following are required in the case of connection in a 4Tr-2R type device structure: to connect an upper electrode of a magnetoresistance element to a wiring line leading to a storage node of a MOS transistor; and to connect a lower electrode to the first power-source terminal.

Examples of material on which not TMR effect, but GMR (Giant Magnetic Resistance) effect works well include a multilayer structure composed of NiFeCo, CoFe, Cu, CoFe and FiFeCo films as shown in FIG. 4B. Examples of material on which CMR (Colossal Magnetic Resistance) effect works well include a multilayer structure composed of PrCrMnO₃, Cr-doped SrTi(Zr)O₃, and PbZrTiO₃ as shown in FIG. 4C.

Examples of the material for a magnetoresistance element which can be changed in resistance value reversibly, and which can hold the state thereof will be described below.

Examples of binary oxide which enables utilization of an electric-field-induced-resistance change include Cu₂O, NiO, TiO₂, HfO₂ and ZrO₂ as shown in FIG. 4D.

Examples of chalcogenide which enables utilization of a phase change include GeSeTe as shown in FIG. 4E. Other examples include a multilayer structure of GeSe/Ag as shown in FIG. 4F.

### Seventh Embodiment

In the examples shown in First to Fifth Embodiments, the memory device is arranged so that a nonvolatile write of data is performed by controlling the direction of electrons flowing through the magnetoresistance elements 203 and 204 thereby to change the condition of the magnetoresistance elements 203 and 204.

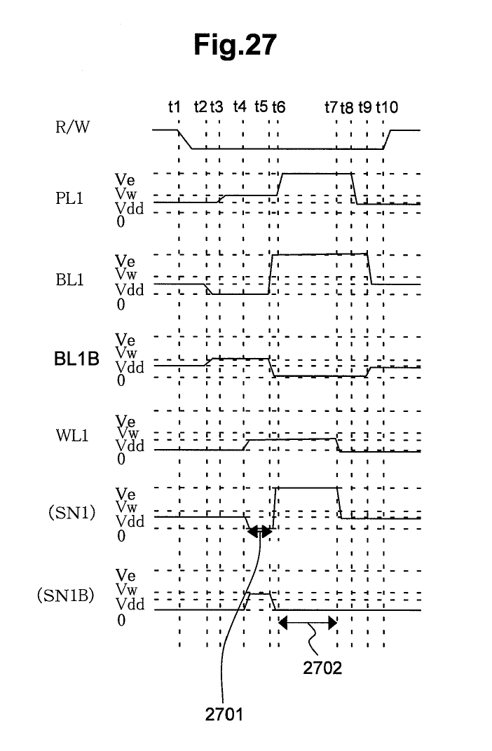

However, a nonvolatile write can be conducted by changing the conditions of magnetoresistance elements by the differences in the voltages applied to the magnetoresistance elements and in the time thereof. In this case, a resistive material, e.g. a chalcogenide GeSeTe, which can be changed in resistance condition according to the differences in voltage applied thereto and time thereof, is used for the magnetoresistance elements 303 and 304 shown in FIG. 10, for example. FIG. 27 shows the timing of an action in connection with a staple portion of the magnetoresistance cell MC during overwrite.

Overwrite is directed by turning the read/write signal R/W to Low level (t1). Then, the bit line BL1 is made to transition from the Vdd level to Vss level (0-volt level), and the bit line BL1B is made to transition from the Vdd level to the Vw level (t2). The control circuit 18 thereafter turns the potential of the cell-source line PL1 to the voltage Vw (t3). Then, the word line WL1 is made Vdd level (select level) (t4), and the n-channel MOS transistors 301 and 302 are turned on. The condition of the magnetoresistance element 304 is changed by the time t5, and thus the write on the side of the node SN1 is completed. Next, the bit line BL1 is changed to the level Ve (Ve>Vw), and the bit line BL1B to the Vss level (0-volt level) (t5). Thereafter the control circuit 18 turns the potential of the cell-source line PL1 to the level Ve (t6). The condition of the magnetoresistance element 303 on the side of the node SN1B is changed by the time t7, and an erase is performed on the side of the node SN1B.

Here, the length of time from t6 to t7 is e.g. 100 nsec. First, a current (e.g. 200 μA), which is relatively larger than a current for write, is forced to flow through the material of the magnetoresistance element already crystallized and put in a lower resistance condition, thereby bringing the material to a temperature above its melting point once. Thereafter the material is made amorphous by rapid cooling. In this way, the magnetoresistance element is made to transition from a low-resistance condition to a high-resistance one, in which the resistance value is higher than that in the low-resistance condition.

While the word line voltage is at Vdd level, the voltage may be different from the voltage at write for changing the material from crystalline to amorphous reliably. In this case, it is appropriate to take e.g. a series of the steps of keeping the word line voltage at 0.7 volts until the time t5 as described above, and switching it to 1.2 volts at the time t5.

After that, the word line WL1 is made the Vss level (non-select level) (t7). Further, the control circuit 18 turns the potential of the cell-source line PL1 to the Vdd level (t8). Then, the bit lines BL1 and BL1B are made the Vdd level (t9), and the R/W signal is turned back to High level (t10). The period from the time t4 to t5 corresponds to a write period 2701, and the period from the time t6 to t7 corresponds to an erase period 2702.

As described above, the low-resistance and high-resistance conditions can be realized by changing the voltage thereby to change a current in quantity even when the direction of current flowing is unchanged.

### Eighth Embodiment

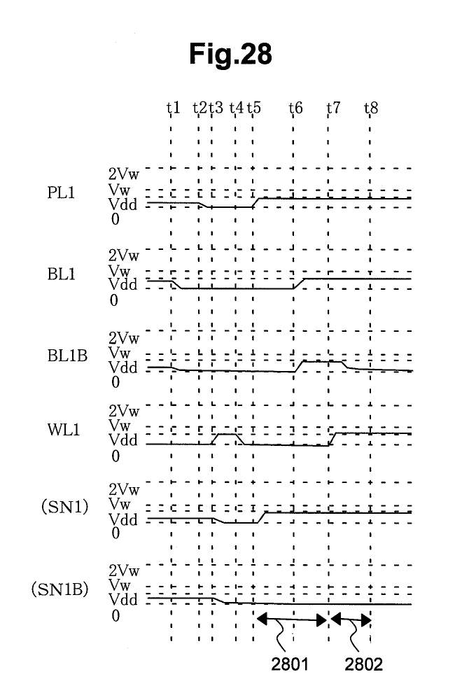

The semiconductor memory device 100 may be arranged so as to conduct a verify for confirming whether or not the magnetoresistance elements 203 and 204, and 303 and 304 are in desired conditions after overwrite of data. The verify can be performed by turning the complementary bit lines to the Vss level (0-volt level) thereby to drive the word line to the select level, and judging whether or not desired data can be held, by means of a sense amplifier, in time. FIG. 28 shows the action timing in the staple portion in this case.

First, to avoid a middle potential, the bit lines BL1 and BL1B are brought to the Vss level (0-volt level) (t1). Then, the cell-source line PL1 is controlled into the Vss level (0-volt level) (t2). Keeping the condition, the word line WL1 is driven to the select level (Vdd level), and the nodes SN1 and SN1B are turned to the Vss level (0-volt level) (t3). In this condition, the word line WL1 is turned to the non-select level (0-volt level) (t4), and the cell-source line PL1 is controlled into the Vdd level (t5). At the point, as the voltage levels at the nodes SN1 and SN1B, High (H) and/or Low (H) level are latched depending on the conditions of the magnetoresistance elements 203 and 204 (or 303 and 304) (t5). Then the bit lines BL1 and BL1B are turned to a predetermined level for read (Vdd level, here) (t6). Thereafter the word line WL1 is driven to select level (Vdd level), and the potential inside the cell is delivered to the bit lines BL1 and BL1B (t7). Then, in the period from the time t7 to t8, the sense amplifier latches the potential of the bit lines BL1 and BL1B, and judges whether or not the potential agrees with an expected value, whereby it becomes possible to conduct the verify. The control circuit 18 can control a principal action during the verify. Incidentally, the period from the time t5 to t7 corresponds to a data-latching period 2801, and the period from the time t7 to t8 corresponds to a verify period 2802.

### Ninth Embodiment

The semiconductor memory device is controlled so that an electric power is fed to the first power-source terminal 207 (309) at the time of read, and therefore the electric power consumed during standby can be reduced. In addition, as no electric power is fed to the first power-source terminal 207 (309) during standby, a malfunction attributed to an alpha-ray-induced soft error during standby can be avoided.

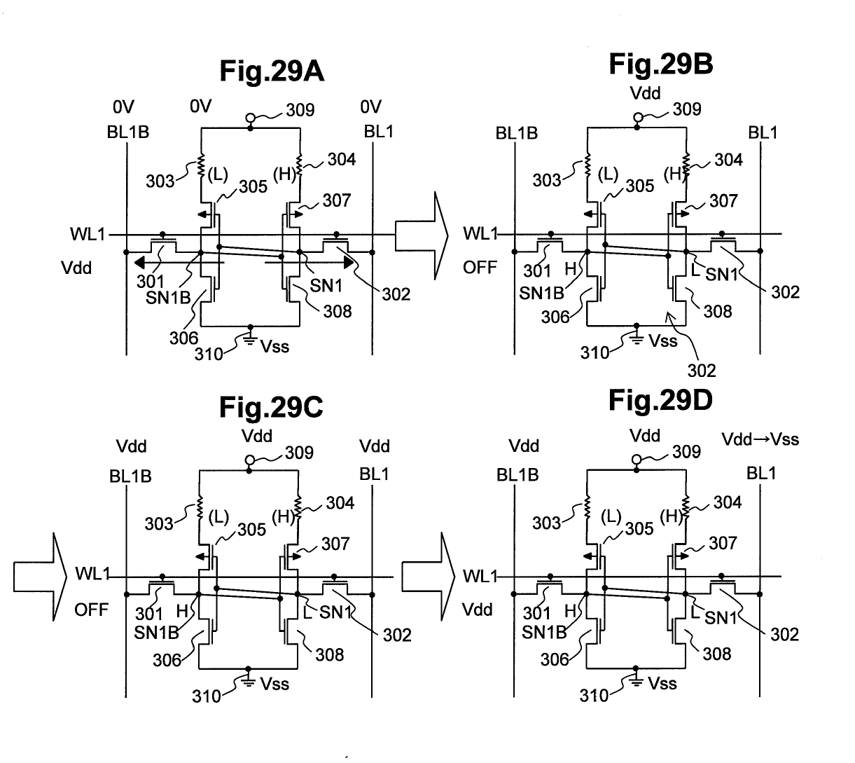

For example, in the semiconductor memory device 100 including 6Tr-2R type memory cells MC shown in FIG. 10, under the condition that the supply of electric power is stopped during standby, the bit lines BL1 and BL1B are at the Vss level (0-volt level), and the first power-source terminal 309 is at the Vss level (0-volt level), as shown in FIG. 29A. In the case of reading data from the memory cell, the first power-source terminal 309 is supplied with a predetermined voltage (e.g. Vdd level) as shown in FIG. 29B, whereby the latch circuit 312 holds potentials depending on the conditions of the magnetoresistance elements 303 and 304. Then, the bit lines BL1 and BL1B are brought to the Vdd level as shown in FIG. 29C. The word line WL1 is thereafter driven to the select level as shown in FIG. 29D, and the n-channel MOS transistors 301 and 302 are turned on. Thus, it becomes possible to read data from the cell.

### Tenth Embodiment

The memory cell array 23 shown in FIG. 1 can be divided into individually selectable memory mats each consisting of a set of memory cells. The memory mats can be selected by a mat-select signal resulting from decode of an address signal. Each memory mat includes: a plurality of word lines; a plurality of bit lines laid out to intersect with the plurality of word lines; and a plurality of memory cells laid out at points where the word lines and bit lines intersect with each other. The semiconductor memory device can be arranged so that supply of electric power to the first power-source terminal 207 or 309 in the magnetoresistance memory cell is enabled only for the selected memory mat. The electric power supply control like this can be performed by the control circuit 18, etc.

As a result of such arrangement, a current flows in a selected memory mat as a result of the selection, whereas a current can be suppressed in the unselected, memory mat.

### Eleventh Embodiment

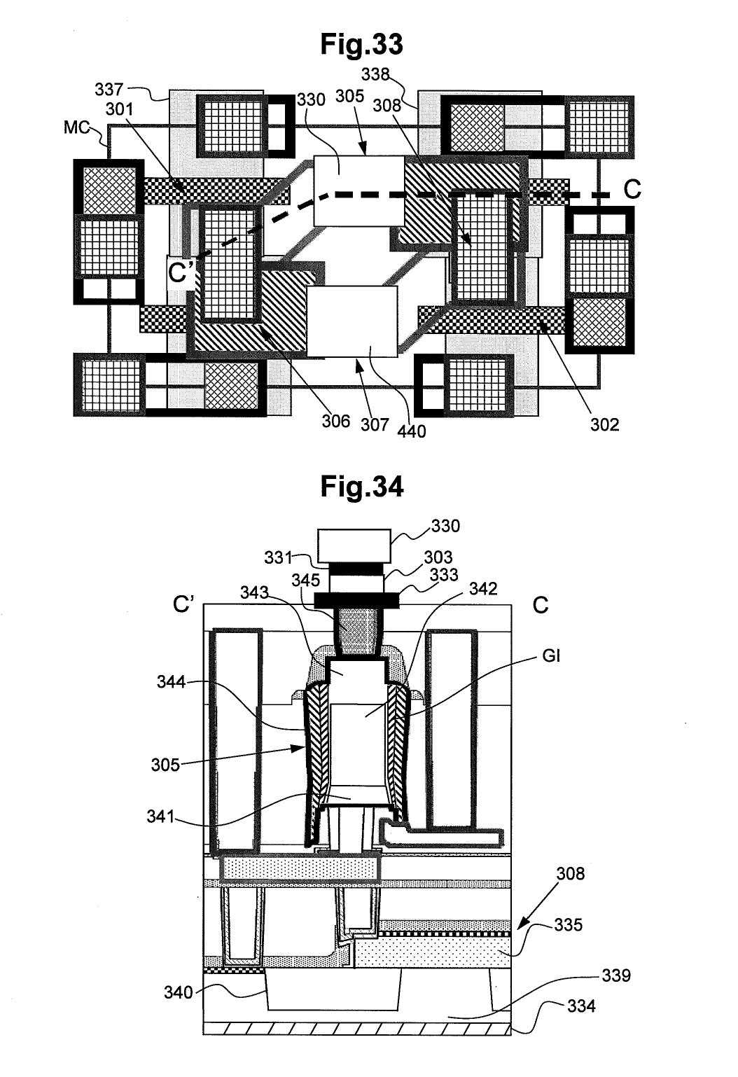

FIG. 33 shows another layout of the magnetoresistance memory cell shown in FIG. 10. FIG. 34 shows a cross section taken along the line C-C′ of FIG. 33.

For the magnetoresistance memory cell MC shown in FIGS. 33 and 34, vertical transistors are used. The memory cell MC is configured as described below.

N-channel MOS transistors 301 and 302, and 306 and 308 are formed on the top face of a semiconductor substrate 334. Specifically, a P-type well 339 is formed on the top face of the semiconductor substrate 334. Active regions 337 and 338 are defined by a device-isolation channel 340 of the P-type well 339, which are each drawn in a rectangle in the drawing. The n-channel MOS transistors 301 and 306 are formed in one active region 337; the MOS transistors share either the source or drain thereof with each other. The n-channel MOS transistors 302 and 308 are formed in the other active region 338; the MOS transistors share the source or drain thereof with each other.

The p-channel MOS transistors 305 and 307 are vertical transistors, and formed in higher positions than the n-channel MOS transistors 301 and 302, and 306 and 308.

The p-channel MOS transistors 305 and 307 each include: a post-like multilayer structure formed by stacking a bottom semiconductor layer (drain) 341, a middle semiconductor layer 342, and a top semiconductor layer (source) 343; and a gate electrode 344 formed on a gate isolation film GI over a side wall of the multilayer structure. While in the example shown in FIGS. 33 and 34, the post-like multilayer structure has the form of a quadrangular prism, the multilayer structure may be a polygonal column with more than four angles, or a column.

The source 343 of the p-channel MOS transistor 305 is coupled to the lower electrode 333 of the magnetoresistance element 303 through the contact hole 345. The upper electrode of the magnetoresistance element 303 is coupled to the metal layer 330. Likewise, the source of the p-channel MOS transistor 307 is coupled to the lower electrode of the magnetoresistance element 304 through the contact hole. The upper electrode of the magnetoresistance element is coupled to the metal layer 330. Further, the metal layer 330 is coupled to the first power-source terminal 309.

According to the arrangement as described above, the p-channel MOS transistors 305 and 307 consist of vertical transistors, on which the magnetoresistance elements 303 and 304 are formed. Therefore, the chip footprint can be made smaller in comparison a planar type SRAM. In other words, in the case of a conventional planar type SRAM, the power-source terminal is connected to a diffusion layer of a p-channel MOS transistor and as such, the connection portion between them is shared by adjacent memory cells, which is an essential structure. In this case, a magnetoresistance element cannot be provided between the power source and p-channel MOS transistor for each cell. To provide a magnetoresistance element for each cell, the diffusion layer of the p-channel MOS transistor must be isolated for each cell as shown in FIGS. 20A and 20B, for example. In contrast, according to the way to arrange the memory cell as shown in FIGS. 33 and 34, by which n-channel MOS transistors 301 and 302, and 306 and 308 are formed on the top face of a semiconductor substrate, and p-channel MOS transistors 305 and 307 are formed above the n-channel MOS transistors, the p-channel MOS transistors 305 and 307, and wiring lines for supplying power source to the transistors are connected independently in the memory cell. Further, as the p-channel MOS transistors 305 and 307, and wiring lines for supplying power source to the transistors are independent of those of a neighboring cell, the magnetoresistance elements 303 and 304 can be disposed between the p-channel MOS transistors 305 and 307 and the power source without changing the layout. Hence, there is the advantage that as to a nonvolatile RAM formed according to the way to arrange the memory cell as shown in FIGS. 33 and 34, the cell footprint is not increased as much as a planar type SRAM.

### Twelfth Embodiment

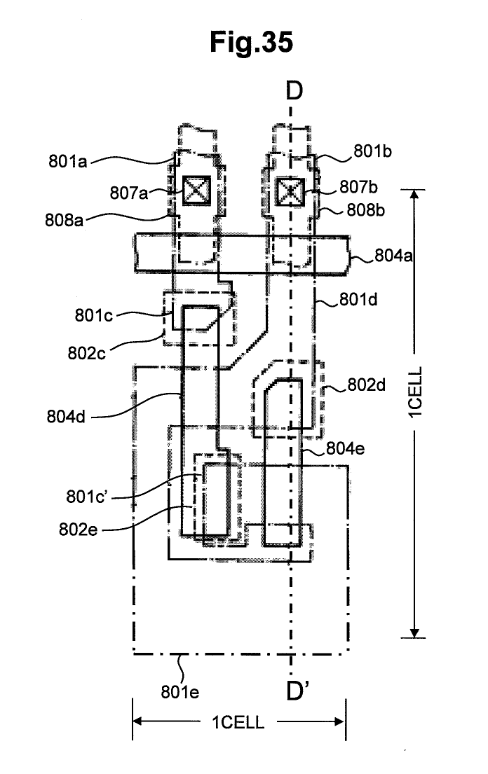

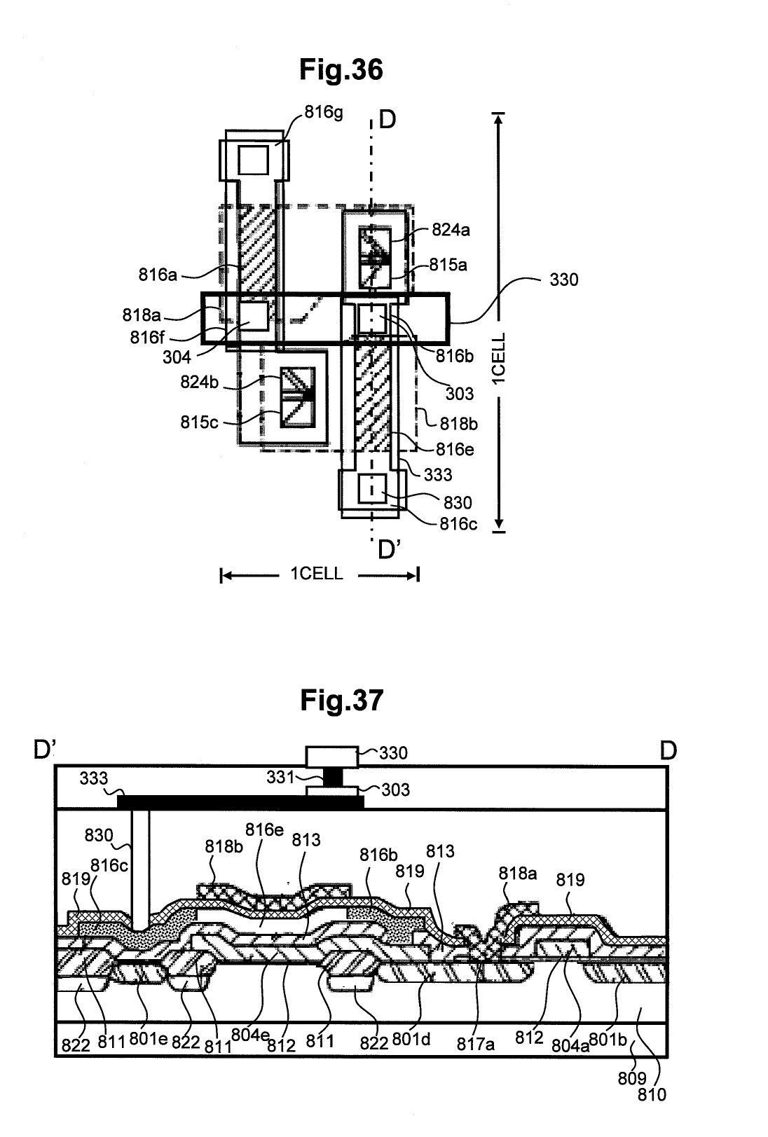

FIGS. 35 and 36 present another layout of the magnetoresistance memory cell shown in FIG. 10. FIG. 37 presents cross section of the magnetoresistance memory cell taken along the line D-D′ of FIGS. 35 and 36. In FIG. 35 shown are parts of the n-channel MOS transistors 301 and 302, and 306 and 308, word line WL1, and bit lines BL1 and BL1B. In FIG. 36, parts of the P-channel MOS transistors 305 and 307, and magnetoresistance elements 303 and 304 are shown.

The n-channel MOS transistors 301 and 302, and 306 and 308 are formed in a p-type well 810 on an n-type silicon substrate 809. Their gate electrodes are all formed from a conductive film of the first layer. The gate electrodes 804d and 804e of the n-channel MOS transistors 306 and 308 are connected to n-type impurity-doped regions 801c′ and 801d, which will form the drains thereof, through contact holes 802e and 802d. Although no special restriction is intended, the gate electrodes are made of n-type or p-type high-density-impurity-doped polycrystalline silicon, a high-melting-point metal such as tungsten (W) or molybdenum (Mo), a compound of high-melting-point metal and silicon, or a composite film of polycrystalline silicon and silicide. The n-type impurity-doped region 801e, which will form a common source of the n-channel MOS transistors 306 and 308, serves as a wiring line at the ground potential.

On the other hand, the p-channel MOS transistors 305 and 307 are formed on a silicon oxide film 813 over the n-channel MOS transistors 306 and 308. Polycrystalline silicon films 816b and 816f of the second layer will make drain regions of the p-channel MOS transistors 305 and 307. Polycrystalline silicon films of the second layer are used for channel regions 816a and 816e of the p-channel MOS transistor. Polycrystalline silicon films 816c and 816g of the second layer are used for source regions of the P-channel MOS transistors. The polycrystalline silicon films 816c and 816g are arranged to be wiring lines independent of each other. This is because they will be connected to the respective magnetoresistance elements 303 and 304. Thus, the polycrystalline silicon layer 816c is coupled to the metal layer 330 through the magnetoresistance element 303. Likewise, the polycrystalline silicon layer 816g is coupled to the metal layer 330 through the magnetoresistance element 304. For example, the polycrystalline silicon layer 816c is coupled to the lower electrode 831 of the magnetoresistance element 303 through a contact hole 830, and the upper electrode 331 of the magnetoresistance element 303 is coupled to the metal layer 330.

The polycrystalline silicon films 816b and 816f of the second layer are connected through contact holes 815b and 815c to impurity-doped regions 801d and 801c of the storage node, or gate electrodes 804d and 804e connected to n-type impurity-doped regions 801d and 801c. Further, polycrystalline silicon films 818a and 818b of the third layer forming gate electrodes of the P-channel MOS transistors are connected through contact holes 824a and 824b to the polycrystalline silicon films 816b and 816f of the second layer. Here, the reference numeral 811 denotes a silicon oxide film, 822 denotes a channel stopper layer, and 819 denotes an isolation film.

As described above, the p-channel MOS transistors 305 and 307 are formed on the silicon oxide film 813 over the n-channel MOS transistors 306 and 308, and then the magnetoresistance elements 303 and 304 are formed thereon. With this arrangement, the increase in the cell footprint can be avoided as in the case of the memory cell according to the eleventh embodiment.

The invention made by the inventor has been described above specifically, however it is not so limited. It is obvious that various changes and modifications may be made without departing from the scope thereof.

While the description hereof is organized into modules each focusing on one embodiment of the invention, the invention is not restricted within the scope of each embodiment. Part or all of each embodiment may be combined with other embodiment appropriately.

In the first and second embodiments, for instance, two transistors (201, 202, etc.) are connected between a pair of bit lines and a storage part of a memory cell. However, the number of transistors so functioning may be decreased to one, or increased to more than two.

The embodiments of the invention can be applied to a memory cell based on a binary oxide or the like, and utilizing an electric-field-induced-resistance change for storing. This is because in such memory cell the resistance value of a resistance element is changed by a voltage applied thereto or a current passed therethrough, in general.

Also, the embodiments of the invention may be appropriately applied to a memory based on chalcogenide or the like, and utilizing the change of phase for storing except that it is preferable for a write action to apply the seventh embodiment. This is because in such memory, the resistance value of a resistance element is changed by the time during which a voltage is applied thereto or the time during which a current is passed therethrough, in general.

In the above description, the case that the invention made by the inventor is applied chiefly to a microcomputer, which is an application field making a background of the invention has been handled. However, the invention is not limited to such example, and it can be applied to various semiconductor devices widely.

The invention can be applied to semiconductor devices including memory cells widely.

What is claimed is:

1. A semiconductor device comprising:
a plurality of memory cells, each including:
a first power-source terminal for supply of a high-potential side power source;
a second power-source terminal for supply of a low-potential side power source;
first and second magnetoresistance elements, each coupled to the first power-source terminal; and
first and second transistors, each coupled to the second power-source terminal,
wherein the first magnetoresistance element and first transistor are connected in series at a first connection node coupled to a control terminal of the second transistor,
the second magnetoresistance element and second transistor are connected in series at a second connection node coupled to a control terminal of the first transistor,
the first and second magnetoresistance elements each include a free layer which can be changed in spin orientation therein by causing current to flow in the layer, and a pinned layer which is less prone to change in spin orientation in comparison to the free layer even though current can flow therein,
the first magnetoresistance element is coupled to the first transistor at its free layer side, and to the first power-source terminal at its pinned layer side, and
the second magnetoresistance element is coupled to the second transistor at its free layer side, and to the first power-source terminal at its pinned layer.

2. The semiconductor device according to claim 1, wherein each memory cell further includes a third transistor through which the first connection node can be coupled to a first bit line; and a fourth transistor through which the second connection node can be coupled to a second bit line paired with the first bit line.

3. A semiconductor device comprising
a plurality of memory cells, each including:
a first power-source terminal for supply of a high-potential side power source;
a second power-source terminal for supply of a low-potential side power source;
a first and second magnetoresistance elements, each coupled to the first power-source terminal;
a first transistor coupled to the first magnetoresistance element;
a second transistor coupled to the second power-source terminal;
a third transistor coupled to the second magnetoresistance element; and
a fourth transistor coupled to the second power-source terminal,
wherein the first and second transistors are connected in series at a first node coupled to a control terminal of the third and fourth transistors,
the third and fourth transistors are connected in series at a second node coupled to a control terminal of the first and second transistors,
the first and second magnetoresistance elements each include a free layer which can be changed in spin orientation therein by causing current to flow in the layer, and a pinned layer fixed in spin orientation therein, and less prone to change in spin orientation in comparison to the free layer even though current can flow therein,
the first magnetoresistance element is coupled to the first power-source terminal at its free layer side, and to the first transistor at its pinned layer, and
the second magnetoresistance element is coupled to the first power-source terminal at its free layer side, and to the third transistor at its pinned layer side.

4. The semiconductor device according to claim 3, wherein each memory cell further includes
a fifth transistor through which the first connection node and the control terminal of the third and fourth transistors can be connected to a first bit line, and
a sixth transistor through which the second connection node and the control terminal of the first and second transistors can be connected to a second bit line paired with the first bit line.

5. A semiconductor device comprising
a plurality of memory cells, and
a control circuit,
wherein each memory cell includes:
a first power-source terminal for supply of a first source voltage;
a second power-source terminal for supply of a second source voltage lower than the first source voltage;
first and second resistance elements, each coupled to the first power-source terminal, having a resistance value electrically and reversibly variable, and capable of holding the resistance value;
first and second transistors, each coupled to the second power-source terminal,
the first resistance element and first transistor are connected in series at a first connection node coupled to a control terminal of the second transistor,
the second resistance element and second transistor are connected in series at a second connection node coupled to a control terminal of the first transistor,
the memory cell further includes
a third transistor through which the first connection node can be coupled to a first bit line;
a fourth transistor through which the second connection node can be coupled to a second bit line in a complementary relation with the first bit line in voltage level, and
on condition that information for data write on the memory cell has been stored by the first and second bit lines, the control circuit controls a voltage level of the first power-source terminal to a level midway between the first and second bit line voltage thereby to enable an overwrite on the memory cell.

6. A semiconductor device comprising
a plurality of memory cells, and
a control circuit,
wherein each memory cell includes:
a first power-source terminal for supply of a first source voltage;
a second power-source terminal for supply of a second source voltage lower than the first source voltage;
first and second resistance elements, each coupled to the first power-source terminal, having a resistance value electrically and reversibly variable, and capable of holding the resistance value; and
first and second transistors, each coupled to the second power-source terminal, in which
the first resistance element and first transistor are connected in series at a first connection node coupled to a control terminal of the second transistor, and
the second resistance element and second transistor are connected in series at a second connection node coupled to a control terminal of the first transistor,
the memory cell further includes:
a third transistor through which the first connection node can be coupled to a first bit line; and
a fourth transistor through which the second connection node can be coupled to a second bit line paired with the first bit line,
on condition that information for write on the memory cell has been stored by the first and second bit lines, the control circuit controls a voltage level of the first power-source terminal to a level closer to one of a pair of bit line levels in the first and second bit lines, and then controls the first power-source terminal voltage to a level closer to the other bit line level, thereby to enable an overwrite on the memory cell.

7. A semiconductor device comprising
a plurality of memory cells, and
a control circuit,
wherein each memory cell includes:
a first power-source terminal for supply of a first source voltage;
a second power-source terminal for supply of a second source voltage lower than the first source voltage;
first and second resistance elements, each coupled to the first power-source terminal, having a resistance value electrically and reversibly variable, and capable of holding the resistance value;
a first transistor coupled to the first resistance element;
a second transistor coupled to the second power-source terminal;
a third transistor coupled to the second resistance element; and
a fourth transistor coupled to the second power-source terminal, in which
the first and second transistors are connected in series at a first connection node coupled to a control terminal of the third and fourth transistors,
the third and fourth transistors are connected in series at a second connection node coupled to a control terminal of the first and second transistors,
the memory cell further includes:
a fifth transistor through which the first connection node and the control terminal of the third and fourth transistors can be connected to a first bit line; and
a sixth transistor through which the second connection node and the control terminal of the first and second transistors can be coupled to a second bit line paired with the first bit line, and
wherein the control circuit brings both the first and second resistance elements to one condition, and then changes one of the first and second resistance elements to another condition, thereby to enable an overwrite on the memory cell.

8. The semiconductor device according to claim 7, wherein the control circuit brings both the first and second bit lines to a voltage level of the second power-source terminal, and in this condition, controls a voltage level of the first power-source terminal to a level midway between high and low levels of the information for write in the first and second bit lines, whereby after an elapse of a predetermined length of time, the information for write on the memory cell is stored by the first and second bit lines, and an overwrite on the memory cell is enabled.

9. A semiconductor device comprising:
a first power source operable to supply a first source voltage;
a second power source operable to supply a second source voltage lower than the first source voltage;
a plurality of memory cells; and
a control circuit operable to control voltage supply to each memory cell,
wherein each memory cell includes
first and second resistance elements, each coupled to the first power source, having a resistance value electrically and reversibly variable, and capable of holding the resistance value,
a first transistor coupled to the first resistance element,
a second transistor coupled to the second power source,
a third transistor coupled to the second resistance element, and
a fourth transistor coupled to the second power source, in which
the first and second transistors are connected in series at a first connection node coupled to a control terminal of the third and fourth transistors, and
the third and fourth transistors are connected in series at a second connection node coupled to a control terminal of the first and second transistors,
the memory cell further includes
a fifth transistor through which the first connection node and the control terminal of the third and fourth transistors can be connected to a first bit line; and
a sixth transistor through which the second connection node and the control terminal of the first and second transistors can be coupled to a second bit line in a complementary relation with the first bit line in level,
wherein the control circuit has a startup sequence control mode after power source cutoff,
in the startup sequence control mode, the control circuit performs the steps of:
making the first power source, and first and second bit lines equal, in voltage level, to the second power source;
in this condition, bringing the fifth and sixth transistors into conduction, thereby to match the second transistor control terminal and the fourth transistor control terminal with each other in potential; and
then restoring potentials of the second transistor control terminal, and fourth transistor control terminal according to resistance conditions of the first and second resistance elements.

10. A semiconductor device comprising:
a first power source operable to supply a first source voltage;
a second power source operable to supply a second source voltage lower than the first source voltage;
a plurality of memory cells; and
a control circuit operable to control voltage supply to each memory cell,
wherein each memory cell includes
first and second resistance elements, each coupled to the first power source, having a resistance value electrically and reversibly variable, and capable of holding the resistance value, and
first and second transistors each coupled to the second power source, in which
the first resistance element and first transistor are connected in series at a first connection node coupled to a control terminal of the second transistor,
the second resistance element and second transistor are connected in series at a second connection node coupled to a control terminal of the first transistor,
the memory cell further includes
a third transistor through which the first connection node can be coupled to a first bit line,
a fourth transistor through which the second connection node can be coupled to a second bit line paired with the first bit line,
wherein the control circuit has a startup sequence control mode after power source cutoff,
in the startup sequence control mode, the control circuit performs the steps of:
making the first power source, and first and second bit lines equal, in voltage level, to the second power source;
in this condition, bringing the third and fourth transistors into conduction, thereby to match the third transistor control terminal and the fourth transistor control terminal with each other in potential; and
then restoring potentials of the third transistor control terminal, and fourth transistor control terminal according to resistance conditions of the first and second resistance elements.

11. The semiconductor device according to claim 2 or 4, comprising:
a plurality of word lines;
a plurality of bit lines laid out to intersect with the plurality of word lines; and
a plurality of voltage-supplying lines,
wherein the memory cells are coupled to the word and bit lines, and arrayed in a matrix form,
the memory cells are organized into memory cell groups each sharing one word line, and
the voltage-supplying lines enable voltage supply to the first power-source terminal for each memory cell group.

12. The semiconductor device according to claim 11, wherein, the voltage-supplying lines are coupled to the corresponding word lines.

13. The semiconductor device according to claim 2 or 4, comprising:
a plurality of word lines;
a plurality of bit lines laid out to intersect with the plurality of word lines; and
a plurality of voltage-supplying lines,
wherein the memory cells are coupled to the word and bit lines, and arrayed in a matrix form,
the magnetoresistance memory cells are organized into memory cell groups each sharing one word line, and
the voltage-supplying lines enable voltage supply to the first power-source terminal for each memory cell group.

14. The semiconductor device according to claim 2 or 4, further comprising:
a plurality of individually selectable memory mats, each composed of the memory cells arrayed in a matrix form; and
a control circuit operable to enable voltage supply to the first power-source terminals in the magnetoresistance memory cells involved in the selected memory mat.

15. A semiconductor device comprising
first, second and third memories, and
a central processing unit capable of accessing the first, second and third memories,
wherein the first memory includes: a first power source operable to supply a first source voltage;
a second power source operable to supply a second source voltage lower than the first source voltage;
first and second resistance elements, each coupled to the first power source, having a resistance value electrically and reversibly variable, and capable of holding the resistance value;
a first transistor coupled to the first resistance element;
a second transistor coupled to the second power source;
a third transistor coupled to the second resistance element; and
a fourth transistor coupled to the second power source, in which the first and second transistors are connected in series at a first connection node coupled to a control terminal of the third and fourth transistors, and
the third and fourth transistors are connected in series at a second connection node coupled to a control terminal of the first and second transistors,
the first memory further includes
a fifth transistor through which a third connection node where the first and second transistors are connected in series, and the control terminal of the third and fourth transistors can be connected to a first bit line, and
a sixth transistor through which a fourth connection node where the third and fourth transistors are connected in series, and
the control terminal of the first and second transistors can be coupled to a second bit line in a complementary relation with the first bit line in level,
wherein the second memory includes
a third power source operable to supply a third source voltage,
a fourth power source operable to supply a fourth source voltage lower than the third source voltage, and
a plurality of memory cells, each including
third and fourth resistance elements each coupled to the third power source, having a resistance value electrically and reversibly variable, and capable of holding the resistance value, and
seventh and eighth transistors each coupled to the third power source, in which the third resistance element and seventh transistor are connected in series at a fifth connection node coupled to a control terminal of the eighth transistor, and the fourth resistance element and eighth transistor are connected in series at a sixth connection node coupled to a control terminal of the seventh transistor,
the memory cell further including a ninth transistor through which the fifth connection node can be coupled to a third bit line, and
a ninth transistor through which the sixth connection node can be coupled to a fourth bit line paired with the third bit line, and
wherein the third memory includes a plurality of memory cells, each including a resistance element and a transistor, which are connected in series.

16. The semiconductor device according to claim 3, further comprising:
a central processing unit capable of accessing the memory cells, wherein in a volatile write mode serving as a mode for access to the memory cell, information is written on the memory cell without changing resistance conditions of the first and second resistance elements, and
in a nonvolatile write mode, information is written on the memory cell while changing the resistance condition of the first or second resistance element.

17. A semiconductor device comprising:
a first power source operable to supply a first source voltage;
a second power source operable to supply a second source voltage lower than the first source voltage; and
a plurality of memory cell, each including
first and second resistance elements, each coupled to the first power source, having a resistance value electrically and reversibly variable, and capable of holding the resistance value, and
first and second transistors each coupled to the second power source,
the first resistance element and first transistor are connected in series at a first connection node coupled to a control terminal of the second transistor,
the second resistance element and second transistor are connected in series at a second connection node coupled to a control terminal of the first transistor,
each memory cell further including
a third transistor through which the first connection node can be coupled to a first bit line, and
a fourth transistor through which the second connection node can be coupled to a second bit line paired with the first bit line,
wherein an overwrite on the first resistance element is enabled by bringing the third and fourth transistors into conduction with a predetermined voltage applied to between the first bit line and first power-source terminal, and
an overwrite on the second resistance element is enabled by bringing the third and fourth transistors into conduction with a predetermined voltage applied to between the second bit line and first power-source terminal.

18. A semiconductor device comprising:
a first power-source terminal for supply of a high-potential side power source;
a second power-source terminal for supply of a low-potential side power source;
a plurality of memory cells, each including first and second resistance elements each coupled to the first power-source terminal,
a first transistor coupled to the first resistance element,
a second transistor coupled to the second power-source terminal,
a third transistor coupled to the second resistance element, and
a fourth transistor coupled to the second power-source terminal, in which the first and second transistors are connected in series,
the third and fourth transistors are connected in series,
a series-connection node of the first and second transistors is coupled to a control terminal of the third and fourth transistors,
a series-connection node of the third and fourth transistors is coupled to a control terminal of the first and second transistors,
each memory cell further including a fifth transistor through which the series-connection node of the first and second transistors, and the control terminal of the third and fourth transistors can be coupled to a first bit line, and
a sixth transistor through which the series-connection node of the third and fourth transistors, and the control terminal of the first and second transistors can be coupled to a second bit line paired with the first bit line,
wherein an overwrite on the first resistance element is enabled by bringing the fifth and sixth transistors into conduction with a predetermined voltage applied to between the first bit line and first power-source terminal,
wherein an overwrite on the second resistance element is enabled by bringing the fifth and sixth transistors into conduction with a predetermined voltage applied to between the second bit line and first power-source terminal.

19. The semiconductor device according to any one of claims 5 to 8, 17 and 18, further comprising: a control circuit operable to enable a verify after overwrite on the memory cell.

20. The semiconductor device according to any one of claims 1 to 4, wherein
in a first read mode serving as a mode for read from the memory cell, in response to a direction for read, voltage supply to the first power-source terminal is started, and then read from the memory cell is enabled, on condition that the first power-source terminal is being supplied with no voltage at first, and
in a second read mode, a read from the memory cell is enabled in response to a direction for read on condition that the first power-source terminal is being supplied with a voltage.

21. The semiconductor device according to claim 15, wherein one of the first and second memories serves as a cache memory in case that the central processing unit read information from the third memory.

22. The semiconductor device according to claim 15, wherein the first memory or second memory and third memory are coupled so that mutual data exchange can be performed.

23. The semiconductor device according to claim 3, wherein the first and third transistors are next to each other with the diffusion layers thereof separated from each other.

24. The semiconductor device according to claim 1 or 2, wherein the free layer of each magnetoresistance element is formed to be sandwiched between the pinned layer and a second pinned layer provided separately from the first pinned layer,
the free layer of the first magnetoresistance element is coupled to the first transistor through the second pinned layer,
the free layer of the second magnetoresistance element is coupled to the second transistor through the second pinned layer.

25. The semiconductor device according to claim 3 or 4, wherein the free layer of each magnetoresistance element is formed to be sandwiched between the pinned layer and a second pinned layer provided separately from the first pinned layer,
the free layer of the first magnetoresistance element is coupled to the first power-source terminal through the second pinned layer, and
the free layer of the second magnetoresistance element is coupled to the first power-source terminal through the second pinned layer.

26. A semiconductor device comprising:
a first power-source terminal for supply of a high-potential side power source;
a second power-source terminal for supply of a low-potential side power source;
a plurality of memory cells, each including
first and second resistance elements each coupled to the first power-source terminal, and
first and second transistors, each coupled to the second power-source terminal, in which the first resistance element and first transistor are connected in series at a first connection node coupled to a control terminal of the second transistor, and
the second resistance element and second transistor are connected in series at a second connection node coupled to a control terminal of the first transistor,
wherein resistance values of the first and second resistance elements can be changed by directions of electron injection thereinto,
resistance elements can be changed from a high-resistance condition to a low-resistance condition by injecting electrons thereinto from sides closer to the first power-source terminal, and
resistance elements can be changed from the low-resistance condition to the high-resistance condition by injecting electrons from a side opposite to the side closer to the first power-source terminal.

27. A semiconductor device comprising:
a first power-source terminal for supply of a high-potential side power source;
a second power-source terminal for supply of a low-potential side power source;
a plurality of memory cells, each including
first and second resistance elements each coupled to the first power-source terminal,
a first transistor coupled to the first resistance element,
a second transistor coupled to the second power-source terminal,
a third transistor coupled to the second resistance element, and
a fourth transistor coupled to the second power-source terminal, in which the first and second transistors are connected in series at a first node coupled to a control terminal of the third and fourth transistors, and
the third and fourth transistors are connected in series at a second node coupled to a control terminal of the first and second transistors,
wherein
resistance values of the first and second resistance elements can be changed by directions of electron injection thereinto,
resistance elements can be changed from a low-resistance condition to a high-resistance condition by injecting electrons thereinto from sides closer to the first power-source terminal, and
resistance elements can be changed from the high-resistance condition to the low-resistance condition by injecting electrons from a side opposite to the side closer to the first power-source terminal.

28. The semiconductor device according to claim 2 or 4, wherein standby states when the device remains powered on include a mode in which voltage supplies to the first power-source terminal, first bit line and second bit line are kept stopped.

29. The semiconductor device according to claim 4, wherein the second, fourth, fifth and sixth transistors are formed on a top face of a semiconductor substrate,
the first and third transistors are formed in positions higher than positions of the second, fourth, fifth and sixth transistors in a direction perpendicular to the top face of the substrate,
the first magnetoresistance element is disposed between the first transistor and first power-source terminal,
the second magnetoresistance element is disposed between the third transistor and first power-source terminal.

30. The semiconductor device according to claim 4, wherein the second, fourth, fifth and sixth transistors are formed on a top face of a semiconductor substrate,
the first and third transistors are formed in positions higher than positions of the second, fourth, fifth and sixth transistors in a direction perpendicular to the top face of the substrate,
the first transistor is formed in a first multilayer structure extending in a direction perpendicular to the top face of the semiconductor substrate, and has a source, channel region and drain formed in the first multilayer structure, and a gate electrode formed on a side wall portion of the first multilayer structure,
the third transistor is formed in a second multilayer structure extending in a direction perpendicular to the top face of the semiconductor substrate, and has a source, channel region and drain formed in the second multilayer structure, and a gate electrode formed on a gate isolation film over a side wall portion of the second multilayer structure,
the source of the first transistor is connected to the first power-source terminal through the first magnetoresistance element formed above the first multilayer structure,
the source of the third transistor is connected to the first power-source terminal through the second magnetoresistance element formed above the first multilayer structure.

31. The semiconductor device according to claim 4, wherein the second, fourth, fifth and sixth transistors are formed on a top face of a semiconductor substrate,
the first and third transistors are formed in positions higher than positions of the second, fourth, fifth and sixth transistors in a direction perpendicular to the top face of the substrate,
a wiring line connecting between the first transistor and first magnetoresistance element, and a wiring line connecting between the third transistor and second magnetoresistance element are formed independently of each other in the memory cell, and independently of corresponding wiring lines of neighboring memory cell.
